(19) United States
(12) Patent Application Publication
(10) Pub. No.: US 2023/0337410 A1
(43) Pub. Date: Oct. 19, 2023

(54) PILLAR-SHAPED SEMICONDUCTOR MEMORY DEVICE AND MANUFACTURING METHOD THEREOF

(71) Applicant: Unisantis Electronics Singapore Pte. Ltd., Singapore (SG)

(72) Inventor: Nozomu HARADA, Tokyo (JP)

(21) Appl. No.: 18/330,064

(22) Filed: Jun. 6, 2023

Related U.S. Application Data
(63) Continuation of application No. PCT/JP20/45497, filed on Dec. 7, 2020.

(51) Int. Cl. H10B 10/00; H01L 29/423

(52) U.S. Cl. CPC H10B 10/125; H01L 29/42392

(57) ABSTRACT

A contact hole is formed on a boundary region between an N⁺ layer connected to a bottom part of a Si pillar forming a select transistor SGT and a P⁺ layer connected to a bottom part of a Si pillar forming a load transistor SGT on an X-X′ line and on a gate TiN layer surrounding a Si pillar forming a load transistor SGT on an XX-XX′ line in an SRAM cell. A conductor W layer is formed in a bottom part of the contact hole. A SiO₂ layer including a hole is formed inside the contact hole on the W layer.

The present application is a Continuation application of PCT/JP2020/045497, filed Dec. 7, 2020, the entire contents of which are incorporated herein by reference.

### BACKGROUND OF THE INVENTION

### Field of the Invention

The present invention relates to a pillar-shaped semiconductor memory device and to a manufacturing method thereof.

### Description of the Related Art

In recent years, three-dimensional transistors are used in LSI (Large Scale Integration). Among such three-dimensional transistors, an SGT (Surrounding Gate Transistor) which is a pillar-shaped semiconductor device is garnering attention as a semiconductor element that provides a highly-integrated semiconductor device. In addition, there is a need for higher integration and higher performance of semiconductor devices having an SGT.

With an ordinary planar MOS transistor, a channel extends in a horizontal direction along an upper surface of a semiconductor substrate. In contrast, a channel of an SGT extends in a vertical direction relative to the upper surface of the semiconductor substrate (for example, refer to Japanese Patent Laid-Open No. H2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Therefore, an SGT enables further densification of a semiconductor device as compared to a planar MOS transistor.

FIG. 4 shows a schematic structural diagram of an N channel SGT. N⁺ layers 121a and 121b, one of which serves as a drain when the other serves as a source, are formed at upper and lower positions inside a Si pillar 120 (hereinafter, a silicon semiconductor pillar will be referred to as a “Si pillar”) having a P or i (intrinsic) conductivity type (an “N⁺ layer” indicates a semiconductor region containing a high concentration of donor impurities. The same description applies hereinafter). A portion of the Si pillar 120 between the N⁺ layers 121a and 121b to serve as a source and a drain is a channel region 122. A gate insulating layer 123 is formed so as to surround the channel region 122. A gate conductor layer 124 is formed so as to surround the gate insulating layer 123. The SGT is constituted of the N⁺ layers 121a and 121b to serve as a source and a drain, the channel region 122, the gate insulating layer 123, and the gate conductor layer 124. The N⁺ layer 121b and a source wiring metal layer S are connected via a contact hole C opened in an insulation layer 125 on the N⁺ layer 121b. Accordingly, an occupied area of the SGT in a plan view corresponds to an occupied area of a single source or drain N⁺ layer of a planar MOS transistor. Therefore, a circuit chip having an SGT enables a further reduction in chip size as compared to a circuit chip having a planar MOS transistor.

In addition, there is a problem that has to be overcome when attempting to further reduce the chip size. As shown in FIG. 4, the contact hole C which connects the source wiring metal layer S and the N⁺ layer 121b is formed on the Si pillar 120 in a plan view. When the reduction of the chip size advances, a distance between the Si pillar 120 and an adjacent Si pillar decreases. Accordingly, an increase in coupling capacitance between electrodes of adjacent SGTs and a drop in yield due to a short-circuit between electrodes of adjacent SGTs become an issue.

FIG. 5 shows a circuit diagram of an SRAM (Static Random Access Memory) cell using an SGT. The present SRAM cell circuit includes two inverter circuits. One of the inverter circuits is constituted of a P channel SGT Pc1 as a load transistor and an N channel SGT Nc1 as a drive transistor. The other inverter circuit is constituted of a P channel SGT Pc2 as a load transistor and an N channel SGT Nc2 as a drive transistor. A gate of the P channel SGT Pc1 and a gate of the N channel SGT Nc1 are connected to each other. A drain of the P channel SGT Pc2 and a drain of the N channel SGT Nc2 are connected to each other. A gate of the P channel SGT Pc2 and a gate of the N channel SGT Nc2 are connected to each other. A drain of the P channel SGT Pc1 and a drain of the N channel SGT Nc1 are connected to each other.

As shown in FIG. 5, sources of the P channel SGTs Pc1 and Pc2 are connected to a supply terminal Vdd. Sources of the N channel SGTs Nc1 and Nc2 are connected to a ground terminal Vss. Selective N channel SGTs SN1 and SN2 are arranged on both sides of the two inverter circuits. Gates of the selective N channel SGTs SN1 and SN2 are connected to a word line terminal WLt. A source and a drain of the selective N channel SGT SN1 are connected to drains of the N channel SGT Nc1 and the P channel SGT Pc1 and to a bit line terminal BLt. A source and a drain of the selective N channel SGT SN2 are connected to drains of the N channel SGT Nc2 and the P channel SGT Pc2 and to an inverted bit line terminal BLRt. In this manner, a circuit having an SRAM cell is constituted of a total of six SGTs including two load P channel SGTs Pc1 and Pc2, two drive N channel SGTs Nc1 and Nc2, and two selective N channel SGTs SN1 and SN2 (for example, refer to U.S. Patent Application Publication No. 2010/0219483). In the SRAM cell, how to reduce parasitic capacitance between electrodes and between connection wiring is a problem. At the same time, how to reduce defects caused by short-circuits between electrodes which accompany densification of SRAM cells is also a problem.

There is a need for higher performance and higher integration in SRAM circuits using an SGT.

### SUMMARY OF THE INVENTION

In order to solve the problems described above, a manufacturing method of a pillar-shaped semiconductor memory device according to the present invention includes the steps of:
forming, on a substrate, first semiconductor pillars which are aligned on a first line in a plan view and which form first SGTs (Surrounding Gate Transistors) erected in a vertical direction, second semiconductor pillars which are adjacent to the first semiconductor pillars and which form second SGTs, third semiconductor pillars which are aligned on a second line being parallel to the first line in a plan view and which form third SGTs erected in the vertical direction, and fourth semiconductor pillars which are adjacent to the third semiconductor pillars and which form fourth SGTs;
forming a first gate insulating layer which surrounds the first semiconductor pillars, a second gate insulating layer which surrounds the second semiconductor pillars, a third gate insulating layer which surrounds the third semiconductor pillars, and a fourth gate insulating layer which surrounds the fourth semiconductor pillars;
forming a first gate conductor layer which surrounds the first gate insulating layer, a second gate conductor layer which surrounds the second gate insulating layer and which protrudes in a direction of the second line in a plan view, a third gate conductor layer which surrounds the third gate insulating layer in a plan view and which protrudes in a direction of the first line in a plan view, and a fourth gate conductor layer which surrounds the fourth gate insulating layer;
forming a first contact hole on a first connection region which connects a first impurity region in a bottom part of the first semiconductor pillars and a second impurity region in a bottom part of the second semiconductor pillars to each other and on the third gate conductor layer which protrudes in a direction of the first line in a plan view and, at the same time, forming a second contact hole on a second connection region which connects a third impurity region in a bottom part of the third semiconductor pillars and a fourth impurity region in a bottom part of the fourth semiconductor pillars to each other and on the second gate conductor layer which protrudes in a direction of the second line in a plan view;
forming a first conductor layer in a bottom part of the first contact hole and, at the same time, forming a second conductor layer in a bottom part of the second contact hole; and
forming a first hole or a first insulation material layer made of a low-permittivity material layer in the first contact hole on the first conductor layer and, at the same time, forming a second hole or a second insulation material layer made of a low-permittivity material layer in the second contact hole on the second conductor layer, wherein
the first SGTs and the fourth SGTs are select transistors of an SRAM memory cell and the second SGTs and the third SGTs are load transistors of an SRAM memory cell.

In the invention described above, desirably, upper end positions of the first hole and the second hole are formed lower than upper end positions of the first gate conductor layer, the second gate conductor layer, the third gate conductor layer, and the fourth gate conductor layer in the vertical direction.

Desirably, in the step of forming the second gate conductor layer, a thickness of the second gate conductor layer in a region in contact with the second contact hole is formed thicker than a thickness of the second gate conductor layer which surrounds the second gate insulating layer.

The invention described above further includes the steps of:
forming a second conductor layer which surrounds the first gate insulating layer, the second gate insulating layer, the third gate insulating layer, and the fourth gate insulating layer, an upper surface position of the second conductor layer being lower than top parts of the first semiconductor pillars, the second semiconductor pillars, the third semiconductor pillars, and the fourth semiconductor pillars in the vertical direction;
forming a first mask material layer which surrounds top parts of the first semiconductor pillars, the second semiconductor pillars, the third semiconductor pillars, and the fourth semiconductor pillars;
forming: a second mask material layer which is connected to the second semiconductor pillars in a plan view, a part of the second mask material layer protruding in a direction of the second line; and a third mask material layer which is connected to the third semiconductor pillars in a plan view, a part of the third mask material layer protruding in a direction of the first line; and
forming the first gate conductor layer, the second gate conductor layer, the third gate conductor layer, and the fourth gate conductor layer by using the first mask material layer, the second mask material layer, and the third mask material layer as masks to etch the second conductor layer, wherein
a film thickness of the second gate conductor layer which overlaps with the second mask material layer in a plan view is formed thicker than a film thickness of the first mask material layer and a film thickness of the third gate conductor layer which overlaps with the third mask material layer in a plan view is formed thicker than a film thickness of the third mask material layer.

In order to solve the problems described above, a pillar-shaped semiconductor memory device according to the present invention includes:
on a substrate, first semiconductor pillars which are aligned on a first line in a plan view and which form first SGTs (Surrounding Gate Transistors) erected in a vertical direction, second semiconductor pillars which are adjacent to the first semiconductor pillars and which form second SGTs, third semiconductor pillars which are aligned on a second line being parallel to the first line in a plan view and which form third SGTs erected in the vertical direction, and fourth semiconductor pillars which are adjacent to the third semiconductor pillars and which form fourth SGTs;
a first gate insulating layer which surrounds the first semiconductor pillars, a second gate insulating layer which surrounds the second semiconductor pillars, a third gate insulating layer which surrounds the third semiconductor pillars, and a fourth gate insulating layer which surrounds the fourth semiconductor pillars;
a first gate conductor layer which surrounds the first gate insulating layer, a second gate conductor layer which surrounds the second gate insulating layer and which protrudes in a direction of the second line in a plan view, a third gate conductor layer which surrounds the third gate insulating layer in a plan view and which protrudes in a direction of the first line in a plan view, and a fourth gate conductor layer which surrounds the fourth gate insulating layer;
a first contact part which extends in a vertical direction above a first connection region which connects a first impurity region in a bottom part of the first semiconductor pillars and a second impurity region in a bottom part of the second semiconductor pillars to each other and on the third gate conductor layer which protrudes in a direction of the first line in a plan view and a second contact part which extends in a vertical direction above a second connection region which connects a third impurity region in a bottom part of the third semiconductor pillars and a fourth impurity region in a bottom part of the fourth semiconductor pillars to each other and on the second gate conductor layer which protrudes in a direction of the second line in a plan view;
a first conductor layer in a bottom part of the first contact part and a second conductor layer in a bottom part of the second contact part; and
a first hole or a first insulation material layer made of a low-permittivity material layer in the first contact part on the first conductor layer and a second hole or a second insulation material layer made of a low-permittivity material layer in the second contact part on the second conductor layer, wherein
the first SGTs and the fourth SGTs are select transistors of an SRAM memory cell and the second SGTs and the third SGTs are load transistors of an SRAM memory cell.

In the invention described above, upper end positions of the first hole and the second hole are lower than upper end positions of the first gate conductor layer, the second conductor layer, the third gate conductor layer, and the fourth gate conductor layer in the vertical direction.

A thickness of the second gate conductor layer in a region in contact with the second contact part is thicker than a thickness of the second gate conductor layer which surrounds the second gate insulating layer.

### BRIEF DESCRIPTION OF THE DRAWINGS

FIGS. 1AA, 1AB and 1AC are a plan view and a sectional structural diagram for explaining a pillar-shaped semiconductor memory device having an SGT and a manufacturing method thereof according to a first embodiment;

FIGS. 1BA, 1BB and 1BC are a plan view and a sectional structural diagram for explaining the pillar-shaped semiconductor memory device having an SGT and a manufacturing method thereof according to the first embodiment;

FIGS. 1CA, 1CB and 1CC are a plan view and a sectional structural diagram for explaining the pillar-shaped semiconductor memory device having an SGT and a manufacturing method thereof according to the first embodiment;

FIGS. 1DA, 1DB and 1DC are a plan view and a sectional structural diagram for explaining the pillar-shaped semiconductor memory device having an SGT and a manufacturing method thereof according to the first embodiment;

FIGS. 1EA, 1EB and 1EC are a plan view and a sectional structural diagram for explaining the pillar-shaped semiconductor memory device having an SGT and a manufacturing method thereof according to the first embodiment;

FIGS. 1FA, 1FB and 1FC are a plan view and a sectional structural diagram for explaining the pillar-shaped semiconductor memory device having an SGT and a manufacturing method thereof according to the first embodiment;

FIGS. 1GA, 1GB and 1GC are a plan view and a sectional structural diagram for explaining the pillar-shaped semiconductor memory device having an SGT and a manufacturing method thereof according to the first embodiment;

FIGS. 1HA, 1HB and 1HC are a plan view and a sectional structural diagram for explaining the pillar-shaped semiconductor memory device having an SGT and a manufacturing method thereof according to the first embodiment;

FIGS. 1IA, 1IB and 1IC are a plan view and a sectional structural diagram for explaining the pillar-shaped semiconductor memory device having an SGT and a manufacturing method thereof according to the first embodiment;

FIGS. 1JA, 1JB, 1JC and 1JD are a plan view and a sectional structural diagram for explaining the pillar-shaped semiconductor memory device having an SGT and a manufacturing method thereof according to the first embodiment;

FIGS. 1KA, 1KB and 1KC are a plan view and a sectional structural diagram for explaining the pillar-shaped semiconductor memory device having an SGT and a manufacturing method thereof according to the first embodiment;

FIGS. 1LA, 1LB and 1LC are a plan view and a sectional structural diagram for explaining the pillar-shaped semiconductor memory device having an SGT and a manufacturing method thereof according to the first embodiment;

FIGS. 1MA, 1MB and 1MC are a plan view and a sectional structural diagram for explaining the pillar-shaped semiconductor memory device having an SGT and a manufacturing method thereof according to the first embodiment;

FIGS. 1NA, 1NB and 1NC are a plan view and a sectional structural diagram for explaining the pillar-shaped semiconductor memory device having an SGT and a manufacturing method thereof according to the first embodiment;

FIGS. 1OA, 1OB and 1OC are a plan view and a sectional structural diagram for explaining the pillar-shaped semiconductor memory device having an SGT and a manufacturing method thereof according to the first embodiment;

FIGS. 1PA, 1PB and 1PC are a plan view and a sectional structural diagram for explaining the pillar-shaped semiconductor memory device having an SGT and a manufacturing method thereof according to the first embodiment;

FIGS. 1QA, 1QB and 1QC are a plan view and a sectional structural diagram for explaining the pillar-shaped semiconductor memory device having an SGT and a manufacturing method thereof according to the first embodiment;

FIGS. 1RA, 1RB and 1RC are a plan view and a sectional structural diagram for explaining the pillar-shaped semiconductor memory device having an SGT and a manufacturing method thereof according to the first embodiment;

FIGS. 1SA, 1SB and 1SC are a plan view and a sectional structural diagram for explaining the pillar-shaped semiconductor memory device having an SGT and a manufacturing method thereof according to the first embodiment;

FIGS. 1TA, 1TB and 1TC are a plan view and a sectional structural diagram for explaining the pillar-shaped semiconductor memory device having an SGT and a manufacturing method thereof according to the first embodiment;

FIGS. 1UA, 1UB and 1UC are a plan view and a sectional structural diagram for explaining the pillar-shaped semiconductor memory device having an SGT and a manufacturing method thereof according to the first embodiment;

FIGS. 2AA, 2AB and 2AC are a plan view and a sectional structural diagram for explaining a pillar-shaped semiconductor memory device having an SGT and a manufacturing method thereof according to a second embodiment;

FIGS. 2BA, 2BB and 2BC are a plan view and a sectional structural diagram for explaining the pillar-shaped semiconductor memory device having an SGT and a manufacturing method thereof according to the second embodiment;

FIGS. 3AA, 3AB and 3AC are a plan view and a sectional structural diagram for explaining a pillar-shaped semiconductor memory device having an SGT and a manufacturing method thereof according to a third embodiment;

FIGS. 3BA, 3BB and 3BC are a plan view and a sectional structural diagram for explaining the pillar-shaped semiconductor memory device having an SGT and a manufacturing method thereof according to the third embodiment;

FIGS. 3CA, 3CB and 3CC are a plan view and a sectional structural diagram for explaining the pillar-shaped semiconductor memory device having an SGT and a manufacturing method thereof according to the third embodiment;

FIG. 4 is a schematic structural diagram showing an SGT according to a conventional example; and

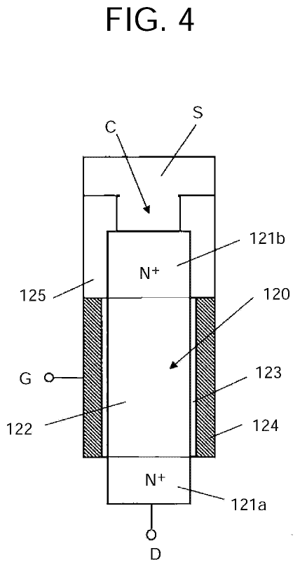

FIG. 5 is an SRAM cell circuit diagram using an SGT according to a conventional example.

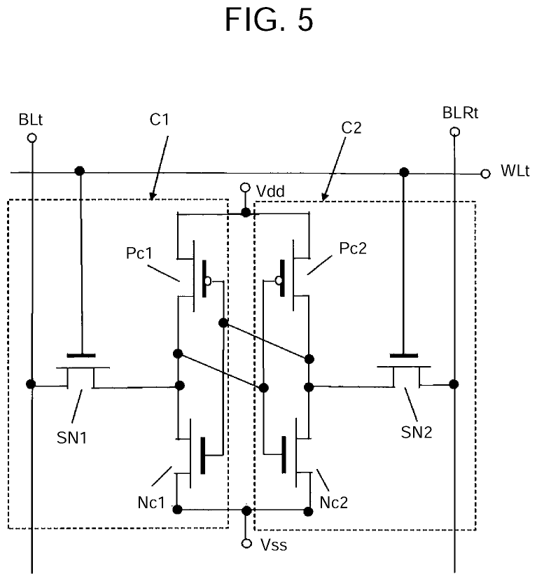

### DETAILED DESCRIPTION OF THE PREFERRED EMBODIMENTS

Hereinafter, a manufacturing method of a pillar-shaped semiconductor memory device according to embodiments of the present invention will be described with reference to the drawings.

### First Embodiment

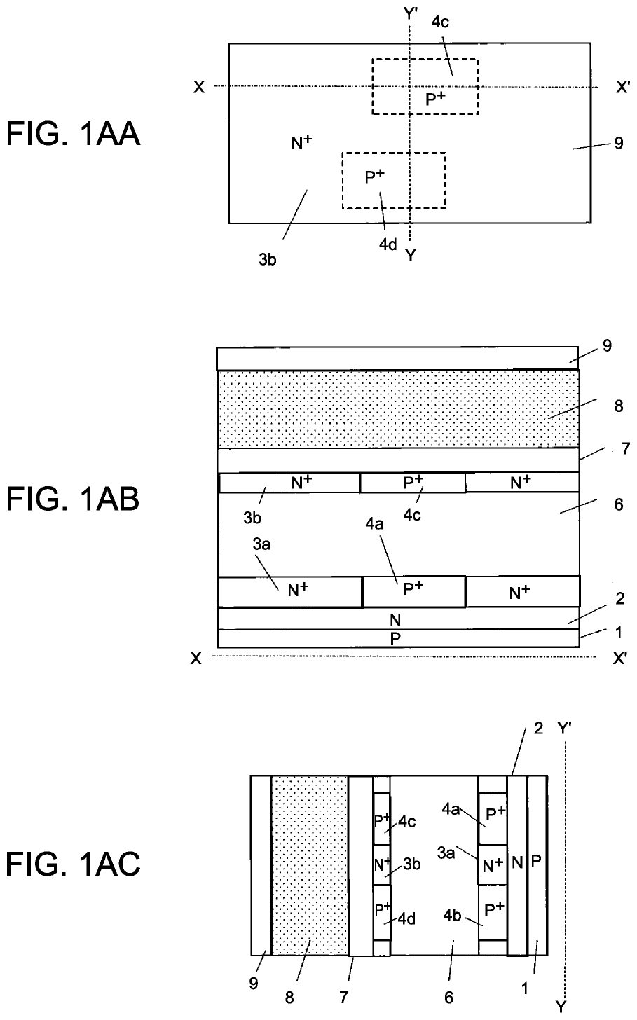

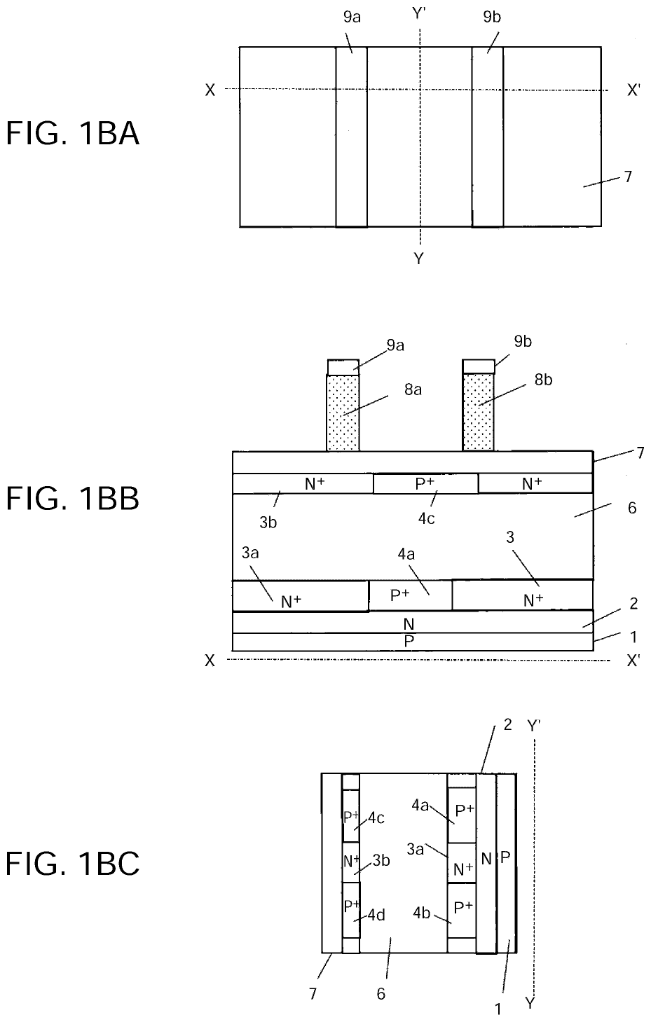

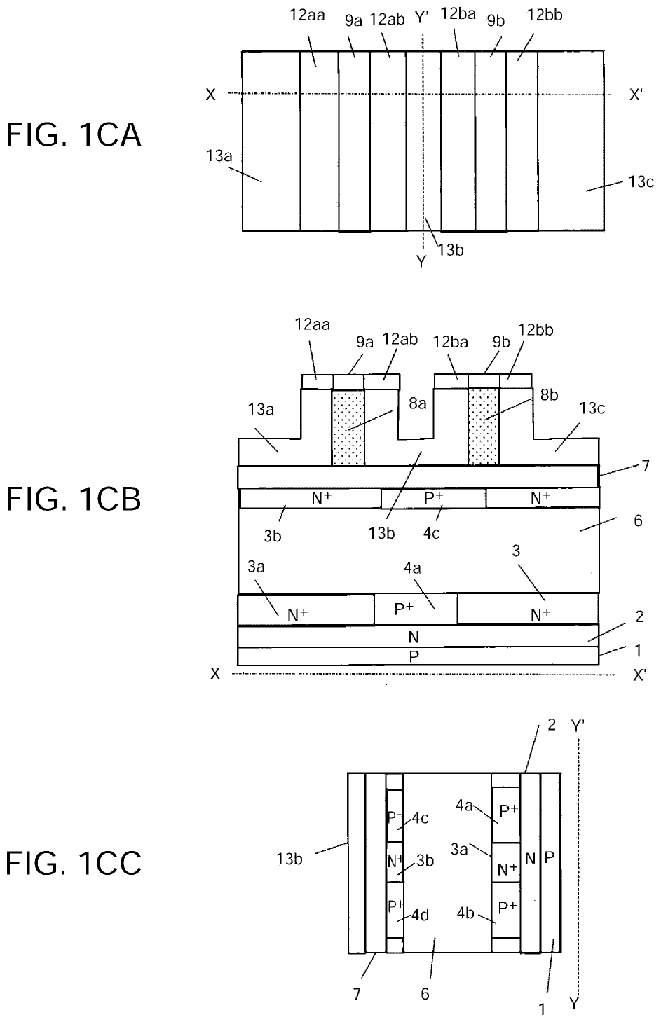

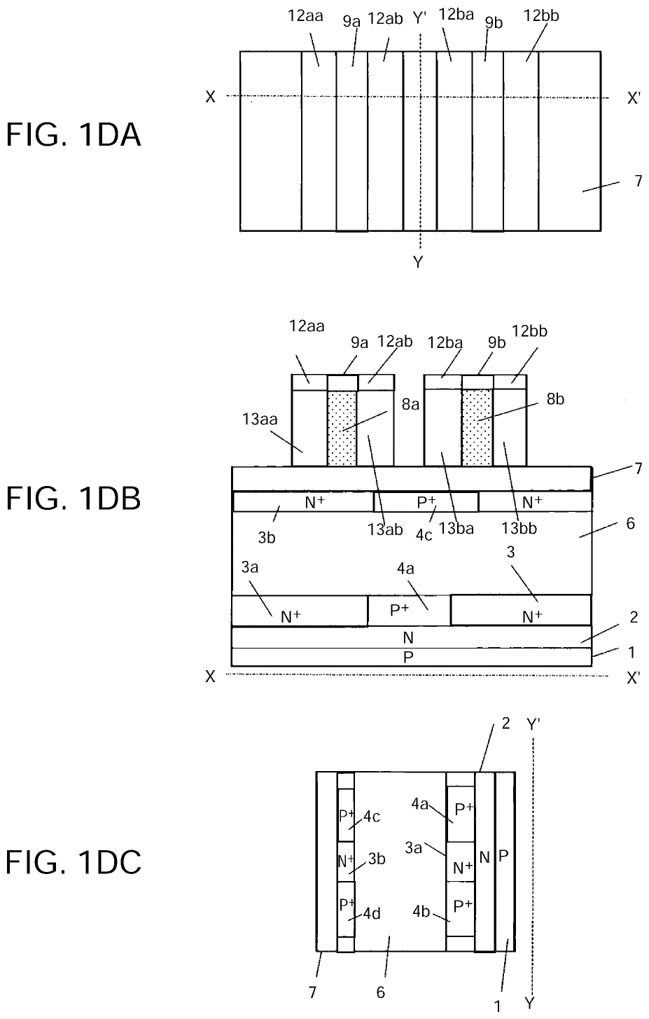

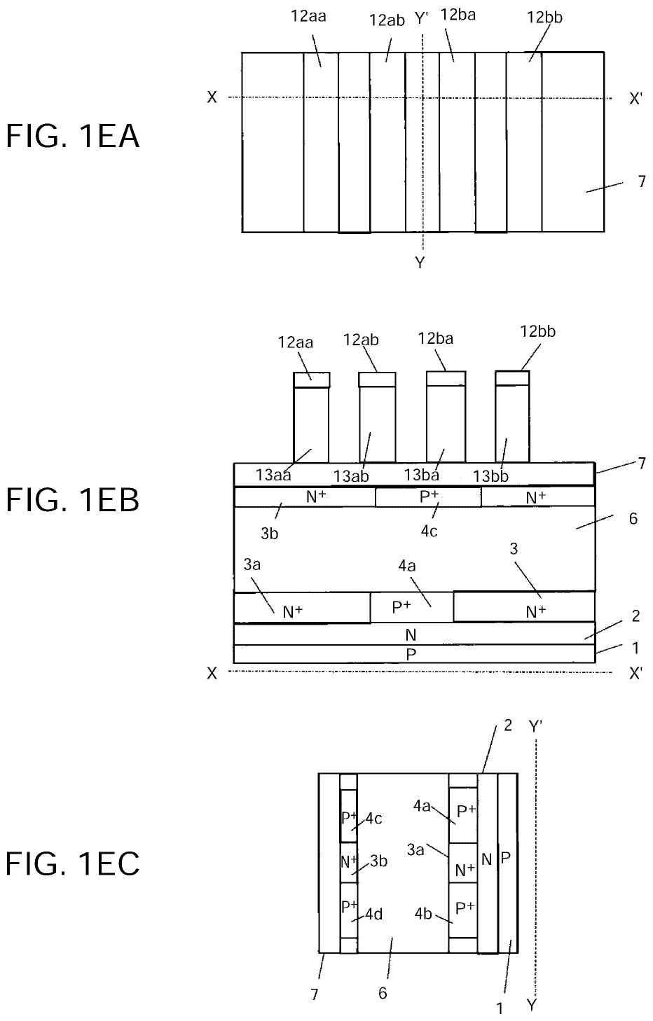

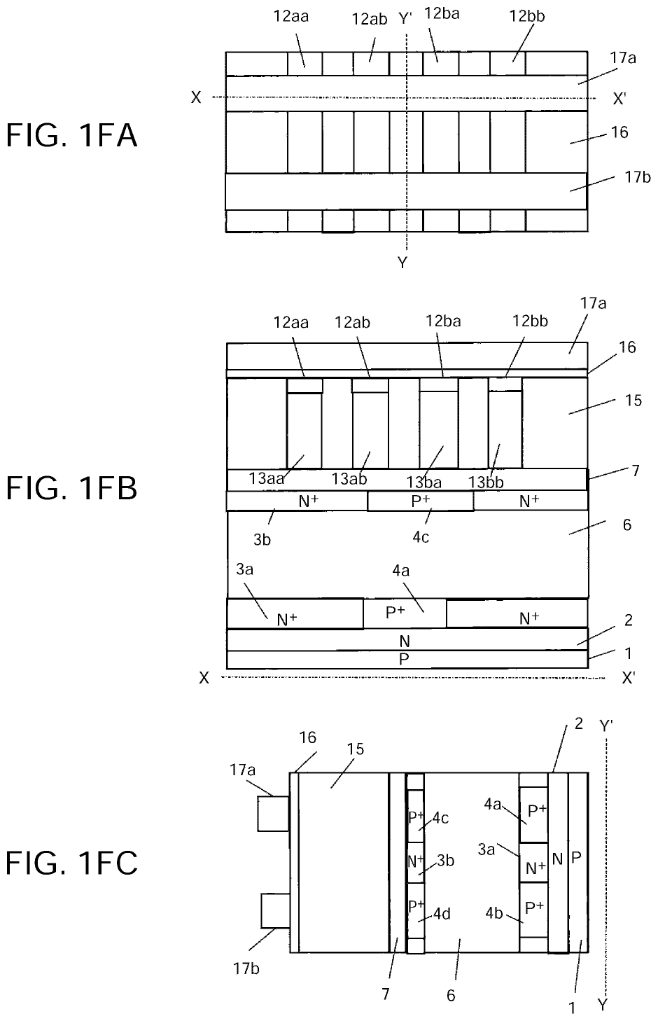

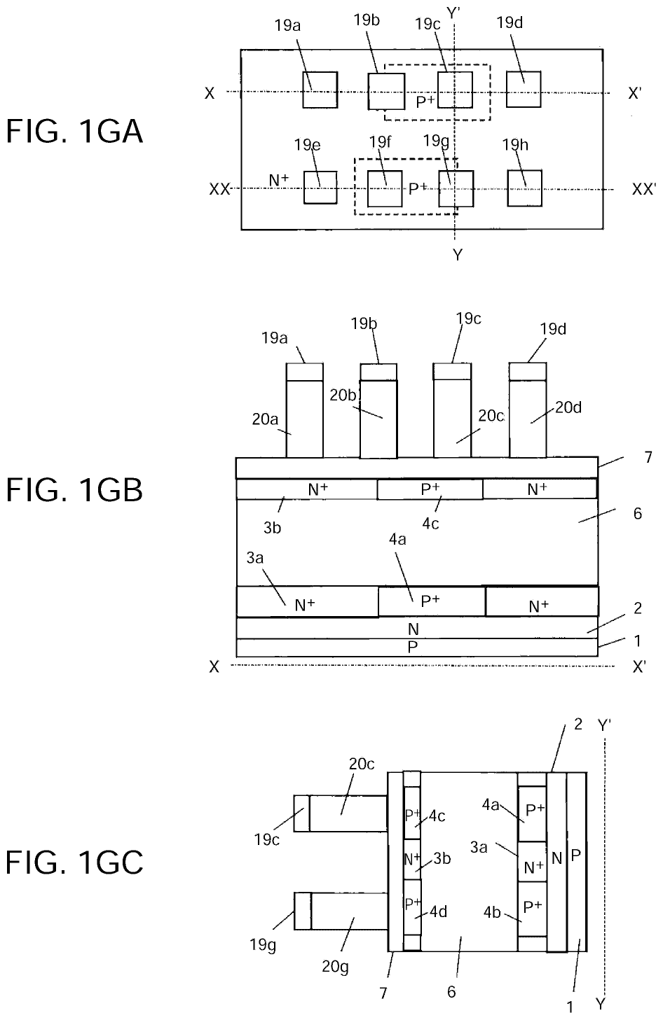

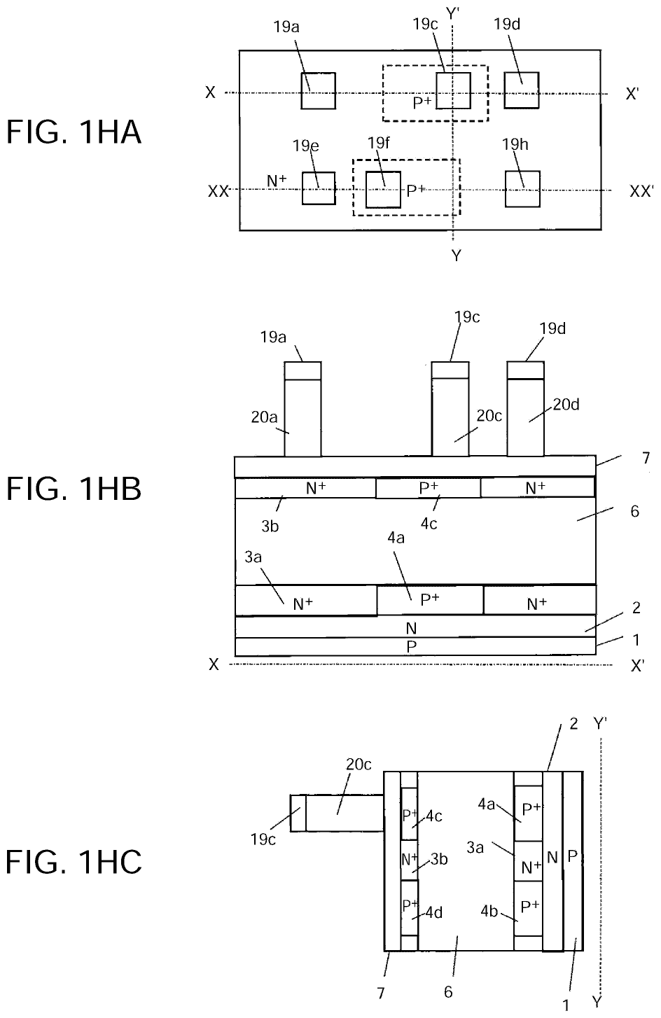

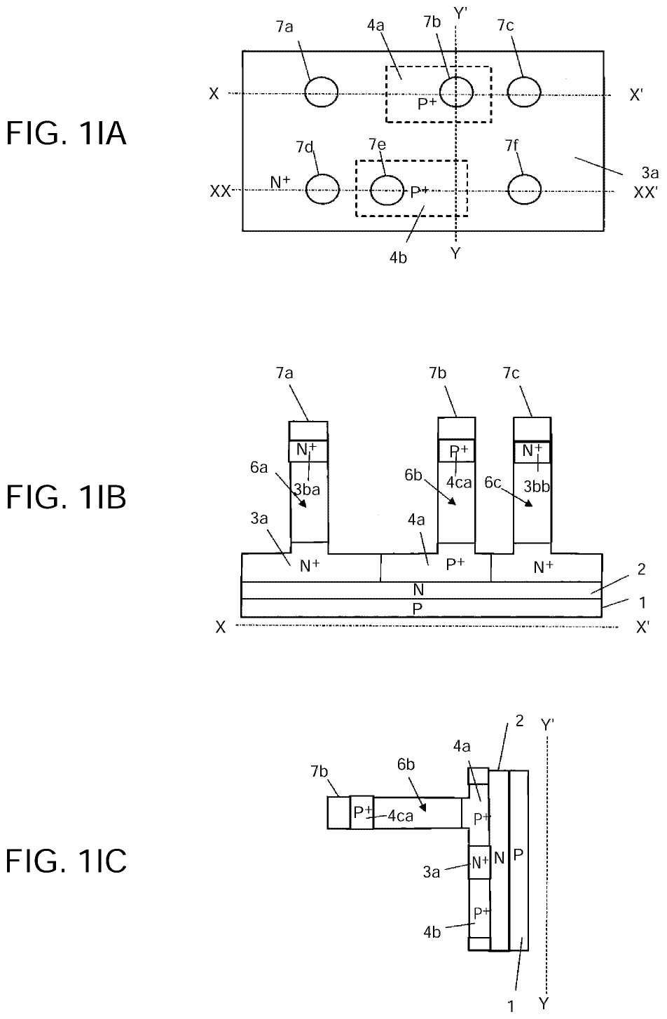

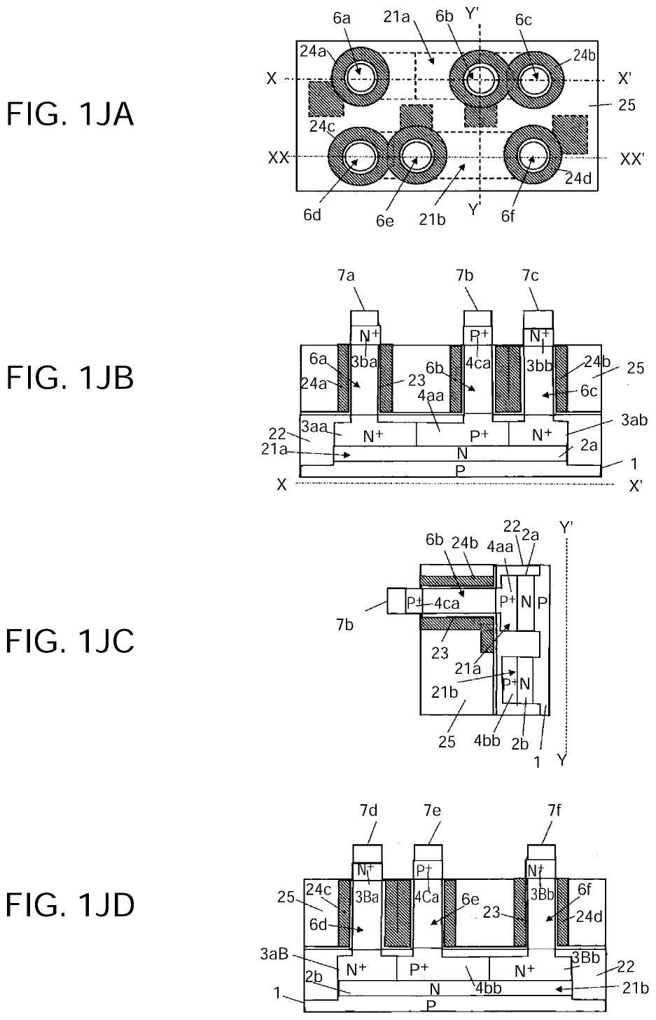

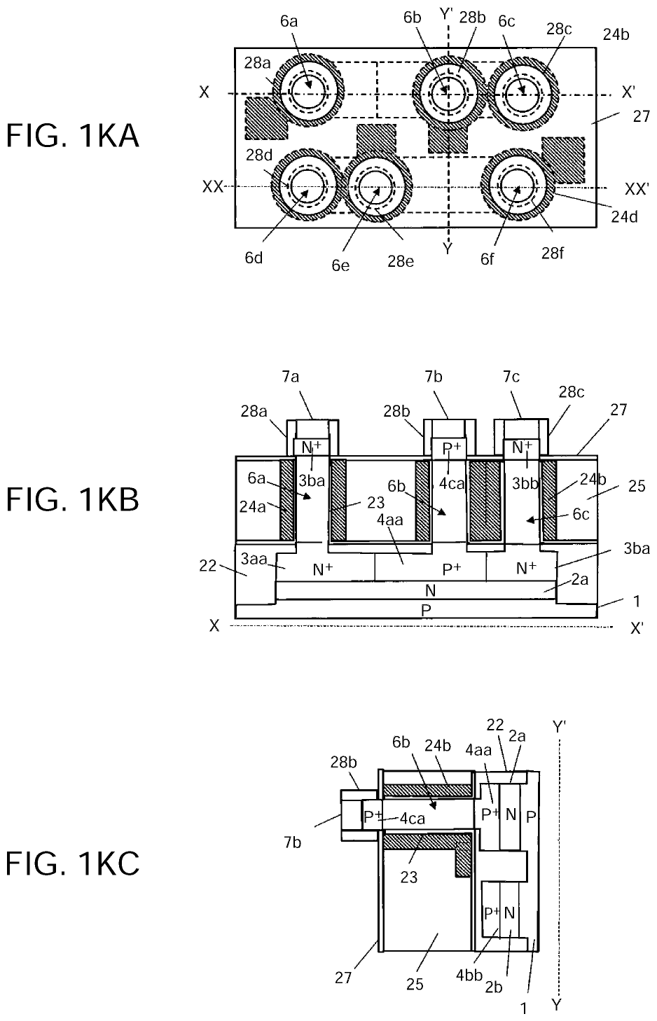

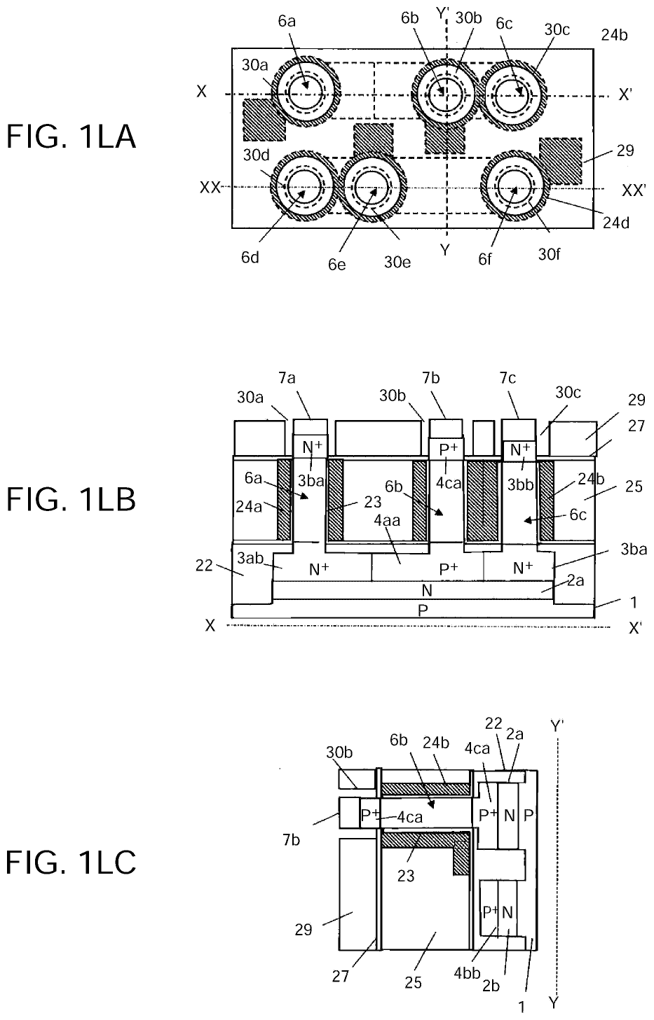

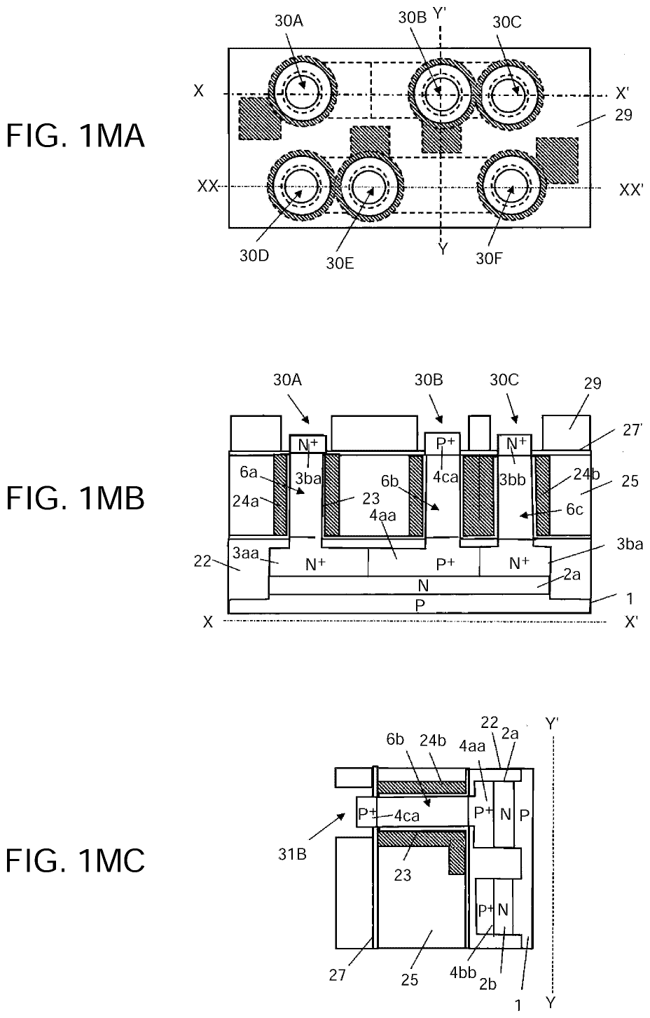

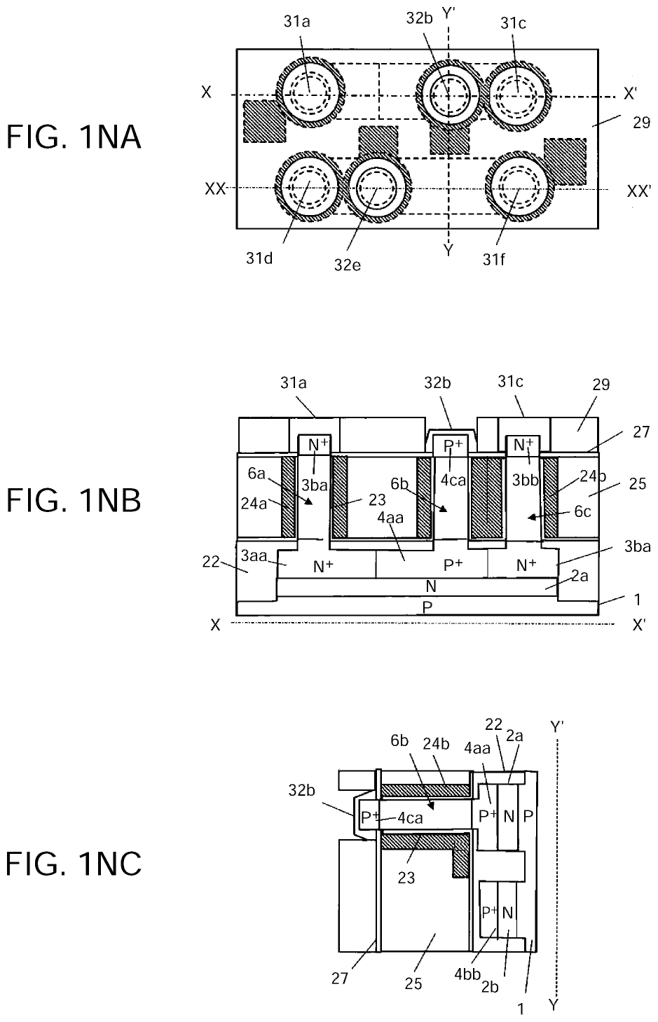

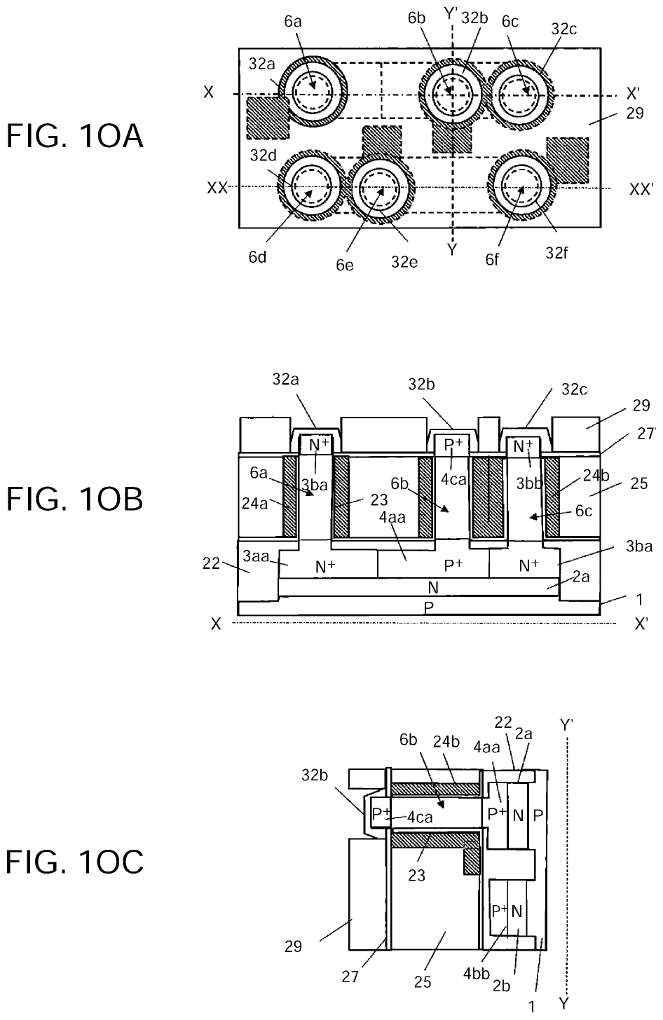

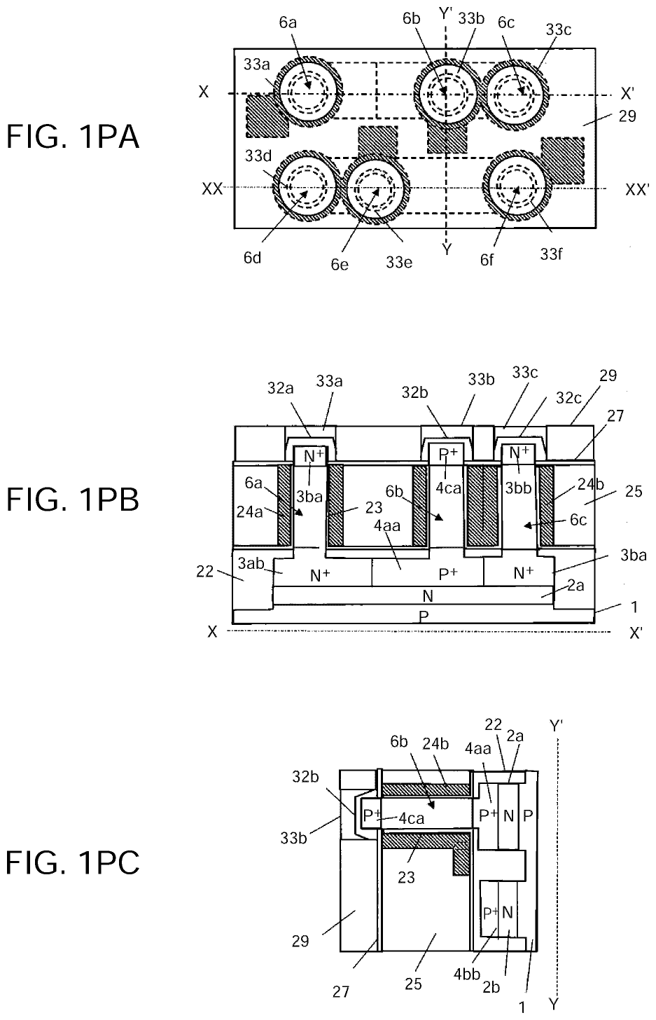

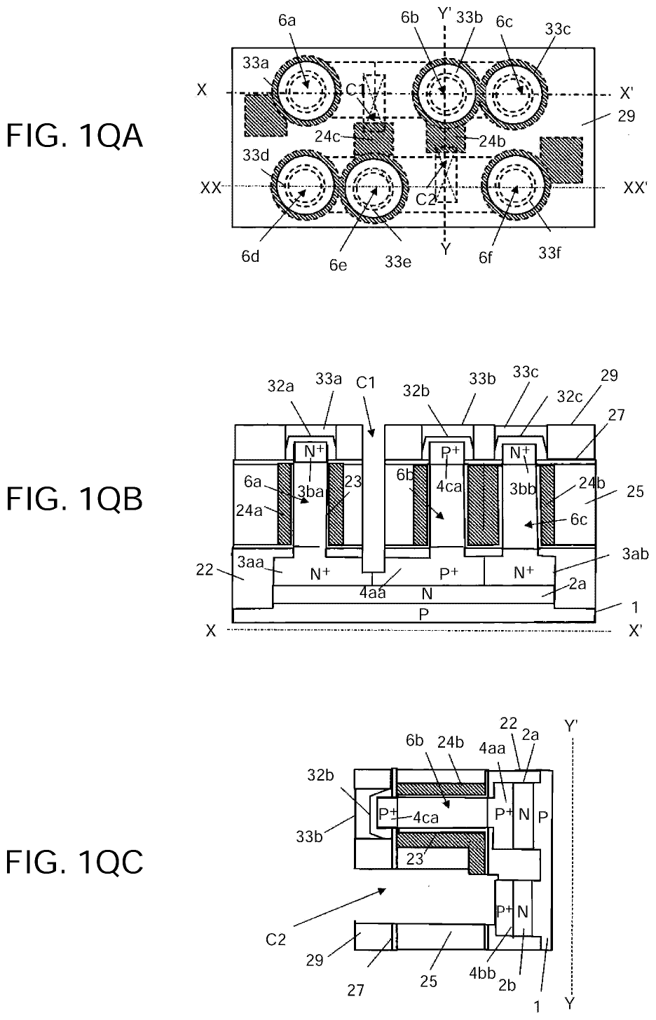

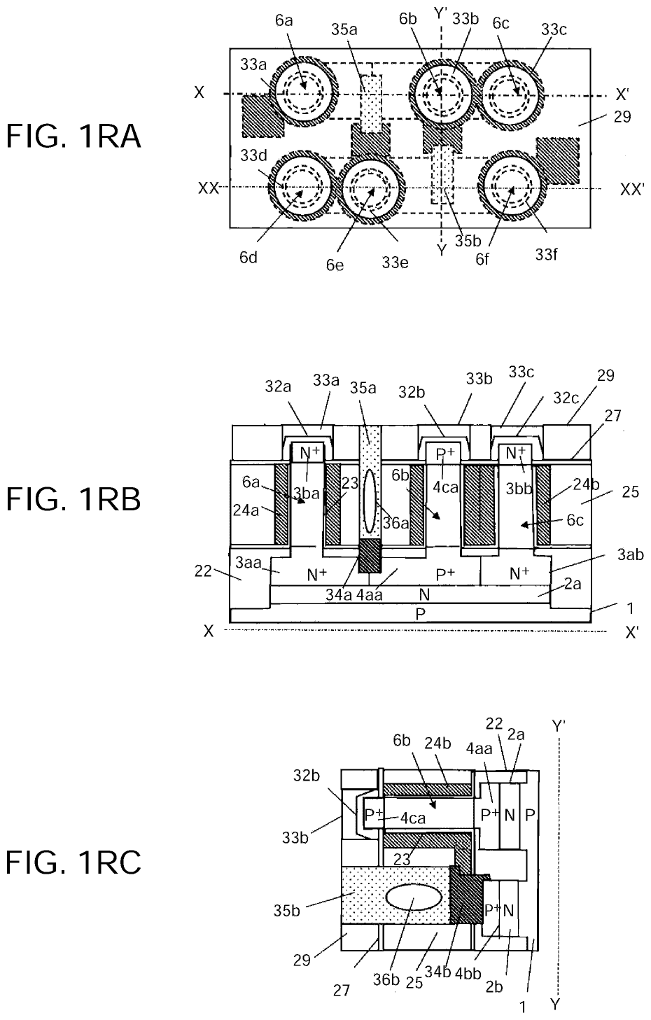

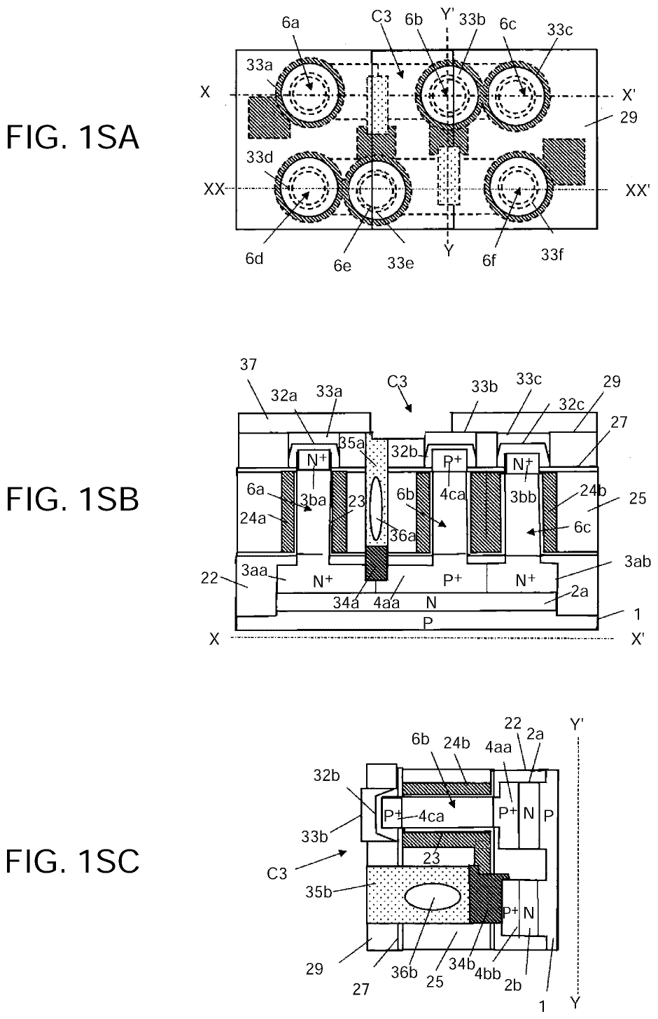

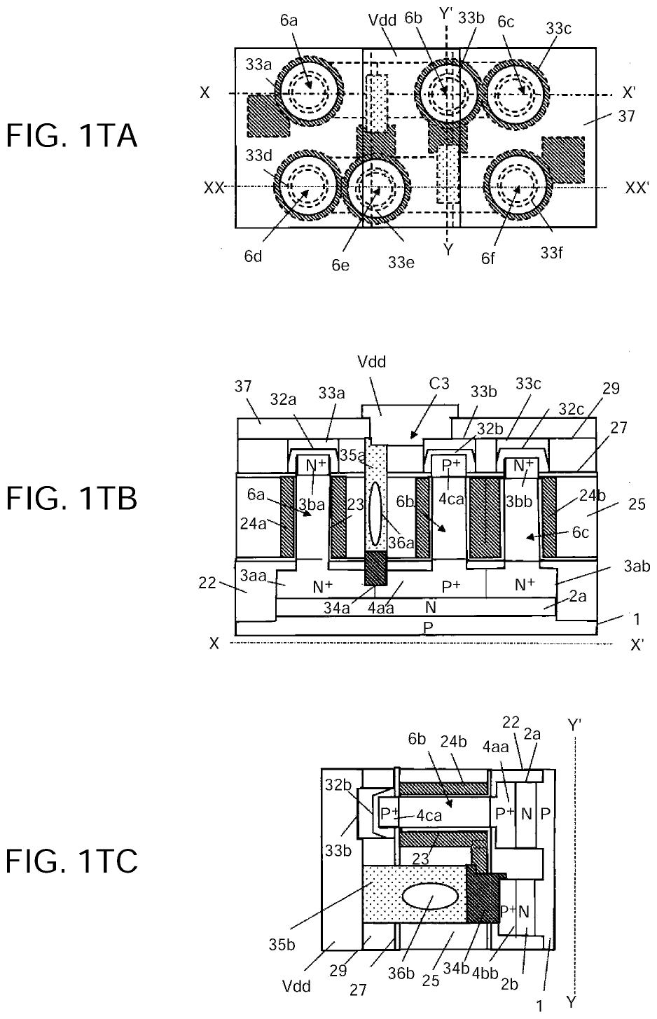

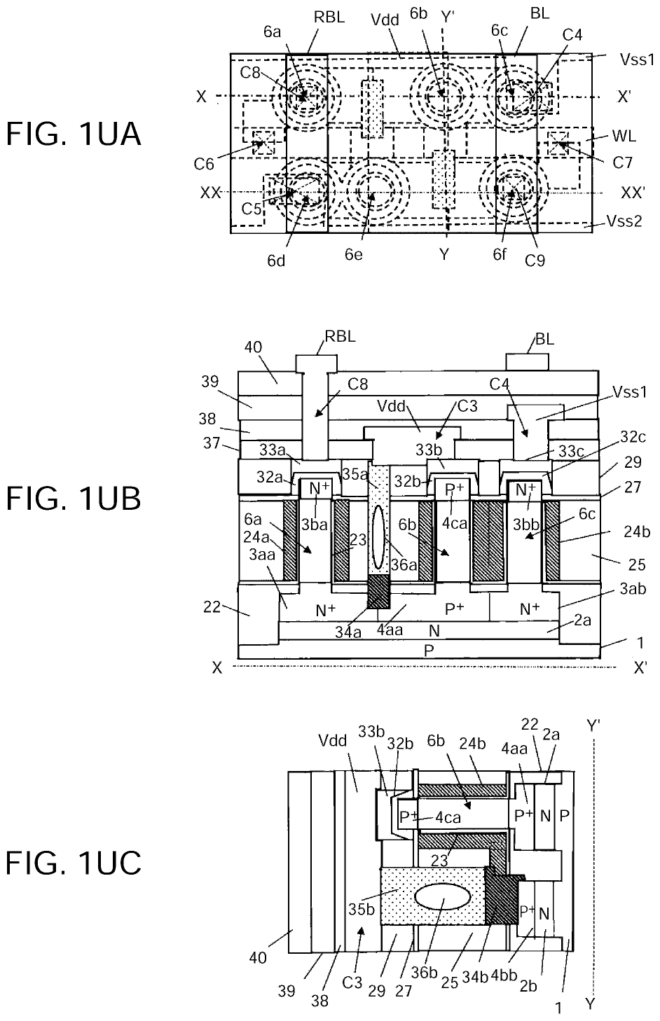

Hereinafter, a manufacturing method of an SRAM cell circuit having an SGT according to a first embodiment of the present invention will be described with reference to FIGS. 1AA to 1AC to 1UA to 1UC. In each diagram, A represents a plan view, B represents a sectional structural diagram taken along an X-X′ line in A, and C represents a sectional structural diagram taken along a Y-Y′ line in A.

As shown in FIGS. 1AA to 1AC, an N layer 2 is formed on a P layer substrate 1 (an example of the “substrate” according to the scope of claims) by an epitaxial crystal growth method. An N⁺ layer 3a and P⁺ layers (a “P⁺ layer” indicates a semiconductor region containing a high concentration of acceptor impurities. The same description applies hereinafter.) 4a and 4b are respectively formed by an epitaxial crystal growth method on a surface layer of the N layer 2. An i layer 6 is formed. An N⁺ layer 3b and P⁺ layers 4c and 4d are formed by the epitaxial crystal growth method on the i layer 6. A mask material layer 7 made up of, for example, a SiO₂ layer, an aluminum oxide (Al₂O₃, hereinafter referred to as AlO) layer, and a SiO₂ layer is formed. A silicon-germanium (SiGe) layer 8 is deposited. A mask material layer 9 made up of a SiO₂ layer and a SiN layer is deposited. Note that the i layer 6 may be formed of N-type or P-type Si containing a small amount of donor impurity atoms or acceptor impurity atoms. In addition, the N⁺ layers 3a and 3b and the P⁺ layers 4a, 4b, 4c, and 4d may be formed by other methods such as an ion implantation method. Furthermore, the mask material layer 9 may be formed of a single material layer or a plurality of material layers containing a SiO₂ layer or a SiN layer or made of other material layers.

Next, using a band-shaped resist layer (not illustrated) formed by a lithographic method and extending in a Y direction in a plan view as a mask, the mask material layer 9 is etched by an RIE (Reactive Ion Etching) method. Using the resist layer as a mask, the mask material layer 9 is subjected to isotropic etching to form band-shaped mask material layers 9a and 9b. Accordingly, widths of the band-shaped mask material layers 9a and 9b are formed to be narrower than a minimum width of resist layers which can be formed by a lithographic method. Next, using the band-shaped mask material layers 9a and 9b as masks, band-shaped SiGe layers 8a and 8b are formed as shown in FIGS. 1BA to 1BC by etching the SiGe layer 8 by, for example, an RIE method.

Next, a SiN layer (not illustrated) is formed on the entire stack by an ALD (Atomic Layered Deposition) method so as to cover the mask material layer 7, the band-shaped SiGe layers 8a and 8b, and the band-shaped mask material layers 9a and 9b. In this case, a cross section of the SiN layer is rounded in a top part thereof. The roundness is desirably formed above the band-shaped SiGe layers 8a and 8b. The entire stack is covered by a SiO₂ layer (not illustrated) by, for example, a flow CVD (Flow Chemical Vapor Deposition) method, and the SiO₂ layer and the SiN layer are polished by CMP (Chemical Mechanical Polishing) so that upper surface positions thereof equal upper surface positions of the band-shaped mask material layers 9a and 9b to form SiN layers 13a, 13b, and 13c. Top parts of the SiN layers 13a, 13b, and 13c are etched to form depressions. The depressions are formed so that positions of bottom parts of the depressions are at positions of lower parts of the band-shaped mask material layers 9a and 9b. The entire stack is coated by a SiN layer (not illustrated), and the entire SiN layer is polished by CMP method so that an upper surface position of the SiN layer is equal to upper surface positions of the mask material layers 9a and 9b. The SiO₂ layer formed by flow CVD is removed. Accordingly, as shown in FIGS. 1CA to 1CC, band-shaped mask material layers 12aa, 12ab, 12ba, and 12bb having same shapes as shapes of top parts of the SiN layers 13a, 13b, and 13c in a plan view are formed on both sides of the band-shaped mask material layers 9a and 9b.

Next, as shown in FIGS. 1DA to 1DC, using the band-shaped mask material layers 9a, 9b, 12aa, 12ab, 12ba, and 12bb as masks, band-shaped SiN layers 13aa, 13ab, 13ba, and 13bb are formed by etching the SiN layers 13a, 13b, and 13c. In this case, widths of the band-shaped SiN layers 13aa, 13ab, 13ba, and 13bb are the same in a plan view.

Next, the band-shaped mask material layers 9a and 9b and the band-shaped SiGe layers 8a and 8b are removed. Accordingly, as shown in FIGS. 1EA to 1EC, the band-shaped SiN layers 13aa, 13ab, 13ba, and 13bb which respectively have, in top parts thereof, the band-shaped mask material layers 12aa, 12ab, 12ba, and 12bb which extend in the Y direction in a plan view and which are arranged parallel to each other are formed on the mask material layer 7.

Next, a SiO₂ layer (not illustrated) by a flow CVD method is formed so as to cover the entire stack. The SiO₂ layer is polished by a CMP method so that an upper surface position thereof equals upper surface positions of the band-shaped mask material layers 12aa, 12ab, 12ba, and 12bb to form a SiO₂ layer 15 as shown in FIGS. 1FA to 1FC. A SiN layer 16 is formed on the SiO₂ layer 15 and the band-shaped mask material layers 12aa, 12ab, 12ba, and 12bb. Band-shaped mask material layers 17a and 17b which extend in the X direction and which are arranged parallel to each other are formed on the SiN layer 16 using a same basic method as the method used to form the band-shaped SiN layers 13aa, 13ab, 13ba, and 13bb.

Next, as shown in FIGS. 1GA to 1GC, using the band-shaped mask material layers 17a and 17b as masks, the SiN layer 16, the band-shaped mask material layers 12aa, 12ab, 12ba, and 12bb, the band-shaped SiN layers 13aa, 13ab, 13ba, and 13bb, and the mask material layer 7 are subjected to RIE etching. The SiN layer 16 and the SiO₂ layer 15 which remain are removed. Accordingly, SiN pillars 20a, 20b, 20c, 20d, 20e, 20f, 20g, and 20h which have rectangular mask material layers 19a, 19b, 19c, 19d, 19e, 19f, 19g, and 19h in top parts thereof are formed in a plan view.

Next, as shown in FIGS. 1HA to 1HC, the rectangular mask material layers 19b and 19g and the SiN pillars 20b and 20g are removed.

Next, using the mask material layers 19a, 19c, 19d, 19e, 19f, and 19h and the SiN pillars 20a, 20c, 20d, 20e, 20f, and 20h as masks, the mask material layer 7 is etched to form mask material layers 7a, 7b, 7c, 7d, 7e, and 7f as shown in FIGS. 1IA to 1IC. In the etching, by performing isotropic etching by, for example, a CDE (Chemical Dry Etching) method, the mask material layers 7a, 7b, 7c, 7d, 7e, and 7f are given a circular shape in a plan view. The CDE etching is not required if the shapes of the mask material layers 7a, 7b, 7c, 7d, 7e, and 7f in a plan view are circular shapes prior to this step. The mask material layers 19a, 19c, 19d, 19e, 19f, and 19h and the SiN pillars 20a, 20c, 20d, 20e, 20f, and 20h are removed. As shown in FIGS. 1IA to 1IC, using the mask material layers 7a, 7b, 7c, 7d, 7e, and 7f as masks, the N⁺ layer 3b, the P⁺ layers 4c and 4d, and the i layer 6 are etched to form a Si pillar 6a (an example of the “first semiconductor pillar” according to the scope of claims), a Si pillar 6b (an example of the “second semiconductor pillar” according to the scope of claims), Si pillars 6c, 6d, and 6e (an example of the “third semiconductor pillar” according to the scope of claims), and a Si pillar 6f (an example of the “fourth semiconductor pillar” according to the scope of claims) on the N⁺ layer 3a and the P⁺ layers 4a and 4b. The Si pillars 6a, 6b, and 6c are formed on an X-X′ line (an example of the “first line” according to the scope of claims) and the Si pillars 6d, 6e, and 6f are formed on an XX-XX′ line (an example of the “second line” according to the scope of claims). An N⁺ layer 3ba is formed in a top part of the Si pillar 6a, a P⁺ layer 4ca is formed in a top part of the Si pillar 6b, an N⁺ layer 3bb is formed in a top part of the Si pillar 6c, an N⁺ layer 3Ba (not illustrated) is formed in a top part of the Si pillar 6d, a P⁺ layer 4Ca (not illustrated) is formed in a top part of the Si pillar 6e, and an N⁺ layer 3Bb (not illustrated) is formed in a top part of the Si pillar 6f.

Next, as shown in FIGS. 1JA to 1JD, the N⁺ layer 3a, the P⁺ layer 4a, the N layer 2, and the P layer substrate 1 which are connected to bottom parts of the Si pillars 6a, 6b, and 6c are etched to form a Si pedestal 21a made up of an upper part of the P layer substrate 1, the N layer 2a, the N⁺ layers 3aa (an example of the “first impurity layer” according to the scope of claims) and 3ab, and the P⁺ layer 4aa (an example of the “second impurity layer” according to the scope of claims). At the same time, as shown in FIG. 1JD which represents a sectional structural diagram along the XX-XX′ line in FIG. 1JA, the N⁺ layer 3a, the P⁺ layer 4b, the N layer 2, and the P layer substrate 1 which are connected to bottom parts of the Si pillars 6d, 6e, and 6f are etched to form a Si pedestal 21b made up of an upper part of the P layer substrate 1, the N layer 2b, the P⁺ layer 4bb (an example of the “third impurity layer” according to the scope of claims), and the N⁺ layers 3aB and 3bB (an example of the “fourth impurity layer” according to the scope of claims). A SiO₂ layer 22 is formed in outer circumferential parts of the N⁺ layers 3aa, 3ab, 3aB, and 3bB, the P⁺ layers 4aa and 4bb, and the N layers 2a and 2b and on the P layer substrate 1. A HfO₂ layer 23 and a TiN layer (not illustrated) are formed by an ALD method so as to cover the entire stack. In this case, TiN layers are in contact with each other by side surfaces thereof between the Si pillars 6b and 6c and the Si pillars 6d and 6e. A TiN layer 24a (an example of the “first gate conductor layer” according to the scope of claims) is formed so as to surround the HfO₂ layer 23 (an example of the “first gate insulating layer” according to the scope of claims) surrounding an outer circumference of the Si pillar 6a, a TiN layer 24b (an example of the “second gate conductor layer” according to the scope of claims) is formed so as to surround the HfO₂ layer 23 (an example of the “second gate insulating layer” according to the scope of claims) in outer circumferences of the Si pillars 6b and 6c, a TiN layer 24c (an example of the “third gate conductor layer” according to the scope of claims) is formed so as to surround the HfO₂ layer 23 (an example of the “third gate insulating layer” according to the scope of claims) in outer circumferences of the Si pillars 6d and 6e, and a TiN layer 24d (an example of the “fourth gate conductor layer” according to the scope of claims) is formed so as to surround the HfO₂ layer 23 (an example of the “fourth gate insulating layer” according to the scope of claims) in an outer circumference of the Si pillar 6f. The entire stack is coated by a SiO₂ layer (not illustrated) and, subsequently, the entire stack is polished by a CMP method so that an upper surface position is equal to upper surface positions of the mask material layers 7a, 7b, 7c, 7d, 7e, and 7f. A planarized SiO₂ layer (not illustrated) is etched back by an RIE method to form a SiO₂ layer 25. Using the mask material layers 7a, 7b, 7c, 7d, 7e, and 7f and the SiO₂ layer 25 as a mask, top parts of the HfO₂ layer 23 and the TiN layers 24a, 24b, 24c, and 24d are removed. The TiN layers 24a, 24b, 24c, and 24d are to serve as a gate conductor layer of the SGTs. The gate conductor layer is a layer which contributes toward setting a threshold voltage of the SGTs and may be formed of a gate conductor layer made of a single layer or made up of a plurality of layers. The gate conductor material layer is formed in contact with entire side surfaces between the Si pillars 6b and 6c and between the Si pillars 6d and 6e. Alternatively, for example, a tungsten (W) layer connected to the TiN layers 24a, 24b, 24c, and 24d may be formed and the layers including the W layer may be used as a gate conductor layer. The W layer may be another conductor material layer. In addition, the HfO₂ layers 23 may be formed by changing film thicknesses or materials on the Si pillars 6a to 6f. The SiO₂ layer 25 may be formed so that an upper surface thereof becomes higher than upper surface positions of the TiN layers 24a to 24d.

Next, as shown in FIGS. 1KA to 1KC, a SiN layer 27 is formed on the SiO₂ layer 25 in the outer circumferential parts of the Si pillars 6a to 6f. The entire stack is coated by a SiO₂ layer (not illustrated). By etching the SiO₂ layer by an RIE method, SiO₂ layers 28a, 28b, 28c, 28d, 28e, and 28f having fixed widths in a plan view are formed in the exposed top parts of the Si pillars 6a to 6f and the side surfaces of the mask material layers 7a to 7f. In this case, the SiO₂ layer 28b and the SiO₂ layer 28c are formed separated from each other. In a similar manner, the SiO₂ layer 28d and the SiO₂ layer 28e are formed separated from each other. Note that the SiN layer 27 need only be at least formed on the TiN layers 24a, 24b, 24c, and 24d which are gate conductor layers. The SiN layer 27 need not be formed when a SiN layer is formed as the SiO₂ layer 25 so that an upper surface thereof becomes higher than upper surface positions of the TiN layers 24a to 24d.

Next, the entire stack is coated by an aluminum oxide (AlO) layer (not illustrated). As shown in FIGS. 1LA to 1LC, the AlO layer is polished by a CMP method so that an upper surface position of the AlO layer equals upper surface positions of the mask material layers 7a to 7f to form an AlO layer 29. The SiO₂ layers 28a, 28b, 28c, 28d, 28e, and 28f which surround the top parts of the Si pillars 6a to 6f are removed to form depressions 30a, 30b, 30c, 30d, 30e, and 30f which surround the top parts of the Si pillars 6a to 6f. Since the SiO₂ layers 28a, 28b, 28c, 28d, 28e, and 28f are formed by self-alignment with respect to the Si pillars 6a to 6f, the depressions 30a, 30b, 30c, 30d, 30e, and 30f are formed by self-alignment with respect to the Si pillars 6a to 6f. Note that the AlO layer 29 may be formed of a single other material layer or a plurality of other material layers.

Next, as shown in FIGS. 1MA to 1MC, the mask material layers 7a, 7b, 7c, 7d, 7e, and 7f are removed to form depressions 30A, 30B, 30C, 30D, 30E, and 30F on the outer circumference and the upper part of the top parts of the Si pillars 6a to 6f. Note that whichever of the SiO₂ layers 28a, 28b, 28c, 28d, 28e, and 28f and the mask material layers 7a, 7b, 7c, 7d, 7e, and 7f may be removed first.

Next, the entire stack is coated by a SiO₂ layer (not illustrated) by a CVD method. As shown in FIGS. 1NA to 1NC, an upper surface position of the SiO₂ layer is polished to the upper surface position of the AlO layer 29 to form SiO₂ layers 31a, 31b (not illustrated), 31c, 31d, 31e (not illustrated), and 31f so as to cover the top parts of the Si pillars 6a to 6f and inside the depressions 30A, 30B, 30C, 30D, 30E, and 30F. The SiO₂ layers 31b and 31e are removed by a lithographic method and a chemical etching method. P⁺ layers 32b and 32e containing acceptor impurities are formed by a selective epitaxial crystal growth method so as to cover the top parts of the Si pillars 6b and 6e and inside the depressions 30B and 30E. The P⁺ layers 32b and 32e are formed so that outer circumferences of the P⁺ layers 32b and 32e do not protrude more outward than outer circumferences of the depressions 30B and 30E in a plan view. Note that, desirably, before forming the P⁺ layers 32b and 32e, processing of thinly oxidizing the top parts of the Si pillars 6b and 6e and then removing the oxide films is performed so as to remove and clean damaged layers among the surface layers of the top parts of the Si pillars 6b and 6e. As the P⁺ layers 32b and 32e, single-crystal P⁺ layers 32b and 32e may be formed using a method other than a selective epitaxial crystal growth method such as a molecular beam crystal growth method. Alternatively, the P⁺ layers 32b and 32e may be formed by applying a coat of a semiconductor layer containing acceptor impurities over its entire surface, polishing the semiconductor layer by a CMP method so that an upper surface position thereof equals the upper surface position of the AlO layer 29, and subjecting the upper surface to a CDE method or chemical etching.

Next, the entire stack is coated by a SiO₂ layer (not illustrated), and by polishing the SiO₂ layer by a CMP method so that an upper surface position of the SiO₂ layer equals the upper surface position of the AlO layer 29, the P⁺ layers 32b and 32e are coated by a SiO₂ layer (not illustrated). The SiO₂ layers 31a, 31c, 31d, and 31f are removed by a lithographic method and a chemical etching method. As shown in FIGS. 10A to 10C, N⁺ layers 32a, 32c, 32d, and 32f containing donor impurities are formed by a selective epitaxial crystal growth method so as to cover the top parts of the Si pillars 6a, 6c, 6d, and 6f and so as to be inside the depressions 30A, 30C, 30D, and 30F. The N⁺ layers 32a, 32c, 32d, and 32f are formed so that outer circumferences of the N⁺ layers 32a, 32c, 32d, and 32f are not more outward than outer circumferences of the depressions 30A, 30C, 30D, and 30F in a plan view. The SiO₂ layer on the P⁺ layers 32b and 32e is removed.

Next, the entire stack is coated by a thin Ta layer (not illustrated) and a W layer (not illustrated). As shown in FIGS. 1PA to 1PC, the W layer is polished by a CMP method so that an upper surface position of the W layer equals the upper surface position of the AlO layer 29 to form W layers 33a, 33b, 33c, 33d, 33e, and 33f which have Ta layers on a side surface and in a bottom part thereof. In this case, the Ta layers between the N⁺ layers 32a, 32c, 32d, and 32f and the P⁺ layers 32b and 32e and the W layers 33a, 33b, 33c, 33d, 33e, and 33f are buffer layers for reducing contact resistance between the two layers. The buffer layer may be a single other material layer or a plurality of other material layers.

Next, as shown in FIGS. 1QA to 1QC, a contact hole C1 (an example of the “first contact hole” according to the scope of claims) is formed on a region (an example of the “first connection region” according to the scope of claims) which includes a boundary between the N⁺ layer 3aa and the P⁺ layer 4aa and on the TiN layer 24c. At the same time, a contact hole C2 (an example of the “second contact hole” according to the scope of claims) is formed on a region (an example of the “second connection region” according to the scope of claims) which includes a boundary between the N⁺ layer 3bB and the P⁺ layer 4bb and on the TiN layer 24b.

Next, the entire stack is coated by a thin buffer Ti layer (not illustrated) and a W layer (not illustrated). As shown in FIGS. 1RA to 1RC, the W layer is etched back by RIE so that an upper surface position of the W layer becomes lower than upper surface positions of the contact holes C1 and C2 to form a W layer 34a (an example of the “first conductor layer” according to the scope of claims) and a W layer 34b (an example of the “second conductor layer” according to the scope of claims) inside the contact holes C1 and C2. A SiO₂ layer (not illustrated) is deposited by a CVD (Chemical Vapor Deposition) method in the contact holes C1 and C2 on the W layers 34a and 34b and on the AlO layer 29. The SiO₂ layer is polished by a CMP method so that an upper surface thereof equals an upper surface of the AlO layer 29 to form a SiO₂ layer 35a (an example of the “first insulation material layer” according to the scope of claims) and a SiO₂ layer 35b (an example of the “second insulation material layer” according to the scope of claims) containing a hole 36a (an example of the “first hole” according to the scope of claims) and a hole 36b (an example of the “second hole” according to the scope of claims) on the W layers 34a and 34b. Note that upper surface positions of the W layers 34a and 34b are formed so as to be lower than or in a vicinity of lower end positions of the gate TiN layers 24a to 24d in the vertical direction. Note that other conductor layers may be used instead of the buffer Ti layer. In a similar manner, other conductor material layers may be used instead of the W layers 34a and 34b. Alternatively, conductor layers which directly correspond to the W layers 34a and 34b may be formed instead of using buffer conductor layers.

Next, the entire stack is coated by a SiO₂ layer (not illustrated). As shown in FIGS. 1SA to 1SC, after forming a SiO₂ layer 37 on the entire stack, a band-shaped contact hole C3 which overlaps with at least a part of the W layers 33b and 33e on the Si pillars 6b and 6e and which extends in the Y direction in a plan view is formed using a lithographic method and an RIE method. Note that a bottom part of the band-shaped contact hole C3 may reach the upper surface of the SiN layer 27.

Next, as shown in FIGS. 1TA to 1TC, the band-shaped contact hole C3 is filled and a supply wiring metal layer Vdd to which the W layers 33b and 33e are connected is formed. Note that the supply wiring metal layer Vdd is not limited to a metal layer and may be formed using a single layer or a plurality of layers of a material layer made of an alloy or a semiconductor containing a large amount of donor or acceptor impurities.

Next, as shown in FIGS. 1UA to 1UC, a SiO₂ layer 38 with a flat upper surface is formed so as to cover the entire stack. A ground wiring metal layer Vss1 is formed via a contact hole C4 formed on the W layer 33c on the N⁺ layer 32c. At the same time, a ground wiring metal layer Vss2 is formed via a contact hole C5 formed on the W layer 33d on the N⁺ layer 32d. A SiO₂ layer 39 with a flat upper surface is formed so as to cover the entire stack. A word wiring metal layer WL is formed via contact holes C6 and C7 formed on the TiN layers 24a and 24d. A SiO₂ layer 40 with a flat upper surface is formed so as to cover the entire stack. An inverted bit output wiring metal layer RBL and a bit output wiring metal layer BL are formed via contact holes C8 and C9 formed on the W layers 33a and 33f on the N⁺ layers 32a and 32f.

Accordingly, an SRAM cell circuit is formed on the P layer substrate 1. In the SRAM cell, a select transistor SGT (an example of the “first SGT” according to the scope of claims) is formed on the Si pillar 6a, a load transistor SGT (an example of the “second SGT” according to the scope of claims) is formed on the Si pillar 6b, a drive transistor SGT is formed on the Si pillar 6c, a drive transistor SGT is formed on the Si pillar 6d, a load transistor SGT (an example of the “third SGT” according to the scope of claims) is formed on the Si pillar 6e, and a select transistor SGT (an example of the “fourth SGT” according to the scope of claims) is formed on the Si pillar 6f. In the present SRAM circuit, a load SGT is formed on the Si pillars 6b and 6e, a drive SGT is formed on the Si pillars 6c and 6d, and a select SGT is formed on the Si pillars 6a and 6f.

Note that, in FIGS. 1RA to 1RC, the SiO₂ layers 35a and 35b including the holes 36a and 36b are effectively low-permittivity material layers. In contrast, other low-permittivity material layers which include or do not include the holes 36a and 36b may be used instead of the SiO₂ layers 35a and 35b. Alternatively, by plugging upper parts of the holes 36a and 36b by, for example, a SiN layer by a CVD method to form holes with a large volume, effective low-permittivity material layers may be formed inside the contact holes C1 and C2. In addition, as long as the holes 36a and 36b are within the SiO₂ layers 35a and 35b even if the upper parts of the SiO₂ layers 35a and 35b are removed after forming the SiO₂ layers 35a and 35b, upper end positions of the holes 36a and 36b in the vertical direction may be set higher than upper ends of the gate TiN layers 24a to 24d.

While the W layer 34a is in direct contact with the N⁺ layer 3aa and the P⁺ layer 4aa in the present embodiment, for example, a conductor layer such as a metal layer or a silicide layer may be provided on the N⁺ layer 3aa and the P⁺ layer 4aa between the Si pillars 6a and 6b in a plan view and the contact hole C1 may be formed on the conductor layer. The same description applies to the contact hole C2. In addition, the P layer substrate 1 is used as a substrate in the present embodiment. Alternatively, the N layer 2 on the P layer substrate 1 may also partially include the substrate. In addition, other substrates such as an SOI (Silicon Oxide Insulator) substrate may be used in place of the P layer substrate.

In addition, the N⁺ layers 3aa, 3ab, 3aB, and 3bB and the P⁺ layers 4aa and 4bb may be formed connected to side surfaces of the bottom parts of the Si pillars 6a to 6f. As described above, the N⁺ layers 3aa, 3ab, 3aB, and 3bB and the P⁺ layers 4aa, 4bb, 4ca, and 4Ca which are to be a source or a drain of an SGT may be formed inside the bottom parts or the top parts of the Si pillars 6a to 6f, or in contact with an outer side of side surfaces of the Si pillars 6a to 6f, and in an outer circumference of the Si pillars 6a to 6f, and the respective layers may be electrically connected by other conductive materials.

The manufacturing method according to the first embodiment produces the following features.

### (Feature 1)

The W layer 34a which connects the N⁺ layer 3aa, the P⁺ layer 4aa, and the gate TiN layer 24c and the SiO₂ layer 35a which is an effective low-permittivity layer between the Si pillars 6a and 6b which are shown in FIGS. 1UA to 1UC and on which a select SGT and a load SGT are to be formed are formed inside the contact hole C1. Accordingly, the W layer 34a and the SiO₂ layer 35a are formed by self-alignment. In a similar manner, the W layer 34b and the SiO₂ layer 35b are formed by self-alignment. The self-aligning formation leads to higher integration of the SRAM cell.

### (Feature 2)

The SiO₂ layer 35a including the hole 36a reduces coupling capacitance between the gate TiN layer 24a of a select SGT and the gate TiN layers 24b of a load SGT and a drive SGT. In a similar manner, the SiO₂ layer 35b including the hole 36b reduces coupling capacitance between the gate TiN layer 24d of a select SGT and the gate TiN layer 24c of a load SGT. The reduction in coupling capacitance leads to higher speeds and lower power consumption of the SRAM device.

### (Feature 3)

As shown in FIGS. 1RA to 1RC, the W layer 34a is formed so that an upper surface thereof becomes lower than or in a vicinity of lower end positions of the gate TiN layers 24a to 24d in the vertical direction. Accordingly, a side surface of the W layer 34a can be formed so that an area of the side surface of the W layer 34a opposing side surfaces of the gate TiN layers 24a and 24b is small or the side surface of the W layer 34a is separated from the side surfaces of the gate TiN layers 24a and 24b. Accordingly, electric short-circuit defects between the W layer 34a and the gate TiN layers 24a and 24b during production can be reduced. In a similar manner, short-circuit defects between the W layer 34b and the gate TiN layers 24c and 24d can be reduced. This contributes toward improving yield of the SRAM device.

### Second Embodiment

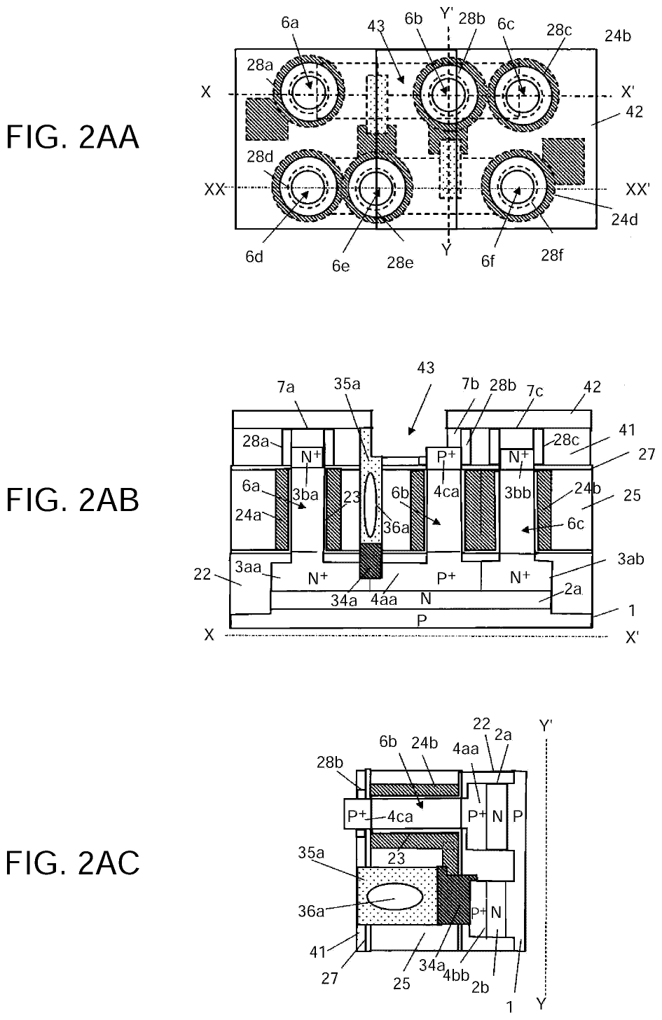

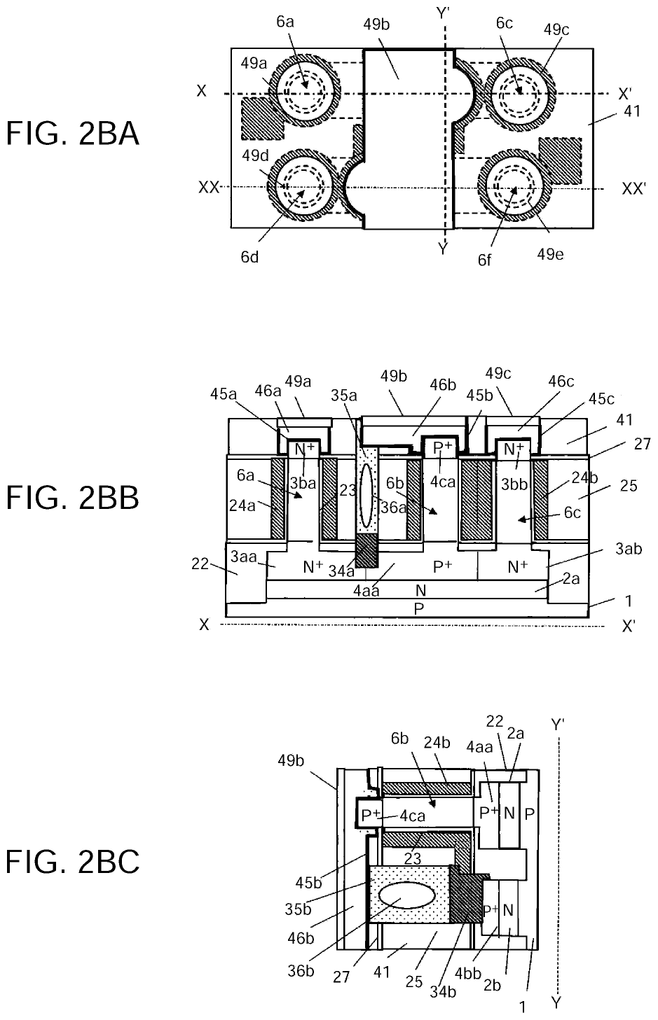

Hereinafter, a manufacturing method of an SRAM cell circuit having an SGT according to a second embodiment of the present invention will be described with reference to FIGS. 2AA to 2AC and 2BA to 2BC. In each diagram, A represents a plan view, B represents a sectional structural diagram taken along an X-X′ line in A, and C represents a sectional structural diagram taken along a Y-Y′ line in A.

In the present embodiment, first, steps shown in FIGS. 1AA to 1AC to FIGS. 1RA to 1RC described in the first embodiment are performed. The entire stack is coated by a resist layer (not illustrated). Using a lithographic method, a resist layer 42 which overlaps with the Si pillars 6b and 6e in a plan view and which has a band-shaped cavity is formed on a SiN layer 41, the mask material layers 7a to 7f, and the SiO₂ layers 28a to 28f as shown in FIGS. 2AA to 2AC. Next, using the resist layer 42 as a mask, the SiN layer 41, the mask material layers 7b and 7e, and the SiO₂ layers 28b, 28e, 35a, and 35b are etched by an RIE method so that upper surface positions thereof are lower than upper surface positions of the top parts of the Si pillars 6b and 6e to form a depression 43. The depression 43 partially overlaps with the SiO₂ layers 35a and 35b in a plan view. Note that a bottom part of the depression 43 may reach the SiN layer 27. In addition, as the resist layer 42, other material layers made of a single layer or made up of a plurality of layers may be used as long as the material layers serve the purpose of an etching mask.

Next, the resist layer 42 is removed. The mask material layers 7b and 7e and the SiO₂ layers 28b and 28e on the Si pillars 6b and 6e are removed. Next, the entire stack is coated by a thin single-crystal Si layer (not illustrated) by an ALD method and a P⁺ layer (not illustrated) containing acceptor impurities by an epitaxial crystal growth method. The P⁺ layer and the thin Si layer are polished so that upper surface positions thereof equal an upper surface position of the SiN layer 41 to form a thin single crystal Si layer 45b and a P⁺ layer 46b on the P⁺ layers 4ca and 4Ca as shown in FIGS. 2BA to 2BC. In a similar manner, N⁺ layers 46a, 46c, 46d, and 46f are formed on the N⁺ layers 3ba, 3bb, 3Ba, and 3Bb. Upper surfaces of the P⁺ layers 46b and 46e and the N⁺ layers 46a, 46c, 46d, and 46f are etched so as to become lower than the upper surface of the SiN layer 41. W layers 49a, 49b, 49c, 49d, and 49e are formed on the P⁺ layers 46b and 46e and the N⁺ layers 46a, 46c, 46d, and 46f. In this case, the holes 36a and 36b are formed so that upper end positions thereof in the vertical direction are lower than the SiN layer 27. Next, by performing the step shown in FIGS. 1TA to 1TC, an SRAM cell circuit is formed on the P layer substrate 1.

The manufacturing method according to the second embodiment produces the following features.

As shown in FIGS. 2BA to 2BC, P⁺ layers 4ca and 4cb and the N⁺ layers 46a, 46c, 46d, and 46f are formed so as to partially overlap with each other in a plan view and so that bottom parts of the P⁺ layers 4ca and 4cb and the N⁺ layers 46a, 46c, 46d, and 46f are on or in contact with the SiN layer 27. In this case, the holes 36a and 36b are formed so that upper end positions thereof in the vertical direction are lower than the SiN layer 27. Accordingly, the holes 36a and 36b are prevented from collapsing in the formation step of the P⁺ layers 4ca and 4cb and the N⁺ layers 46a, 46c, 46d, and 46f. This indicates that the SiO₂ layers 35a and 35b which are effective low-permittivity layers and the P⁺ layer 46b can be formed so as to overlap with each other in a plan view. As a result, densification of the SRAM cell can be achieved.

### Third Embodiment

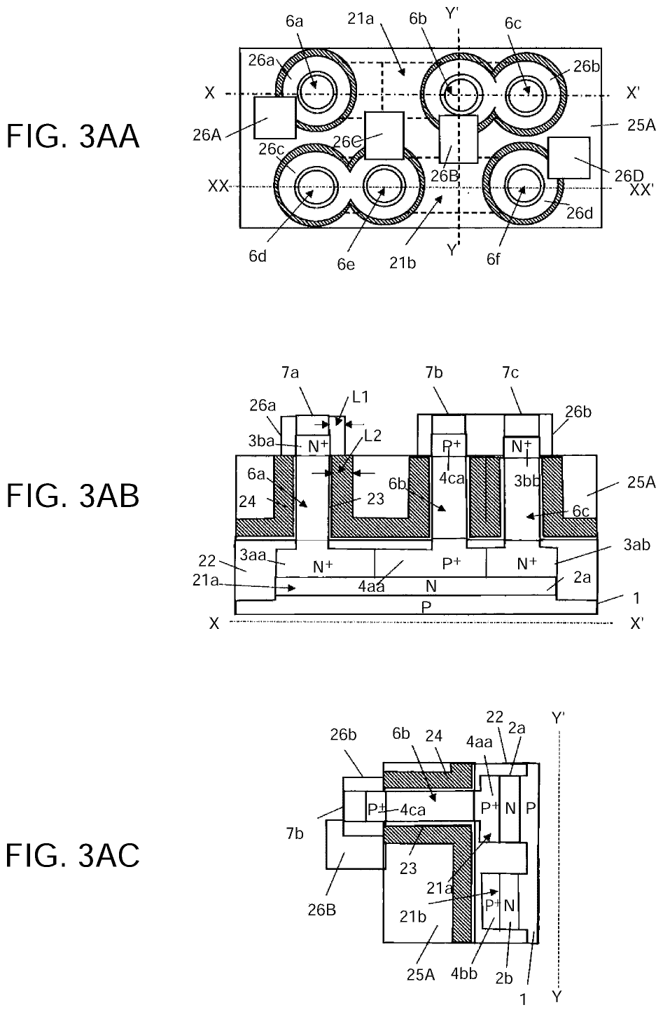

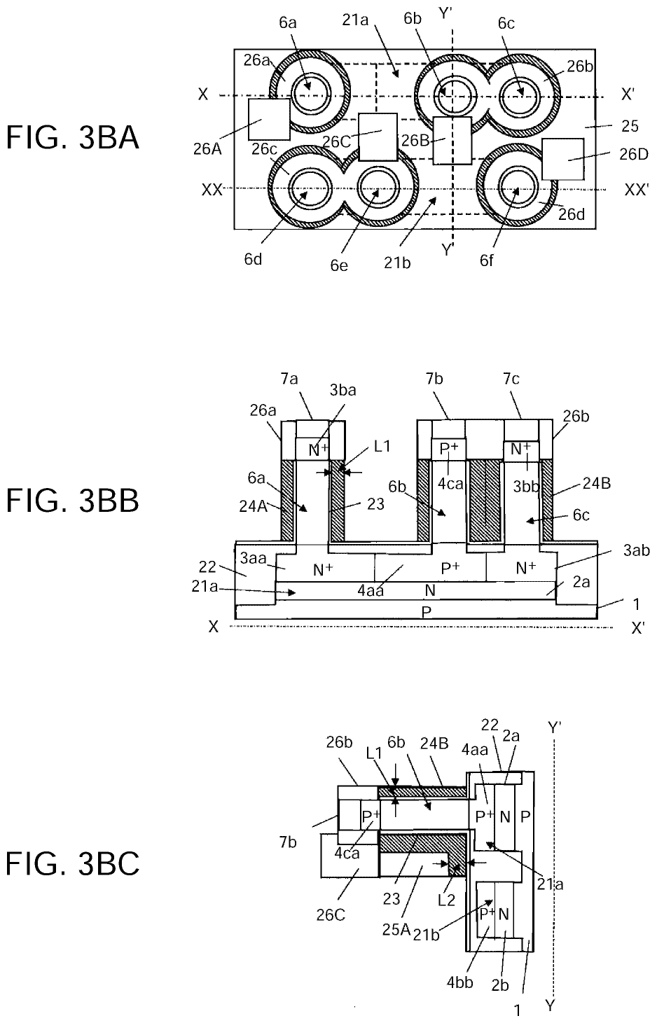

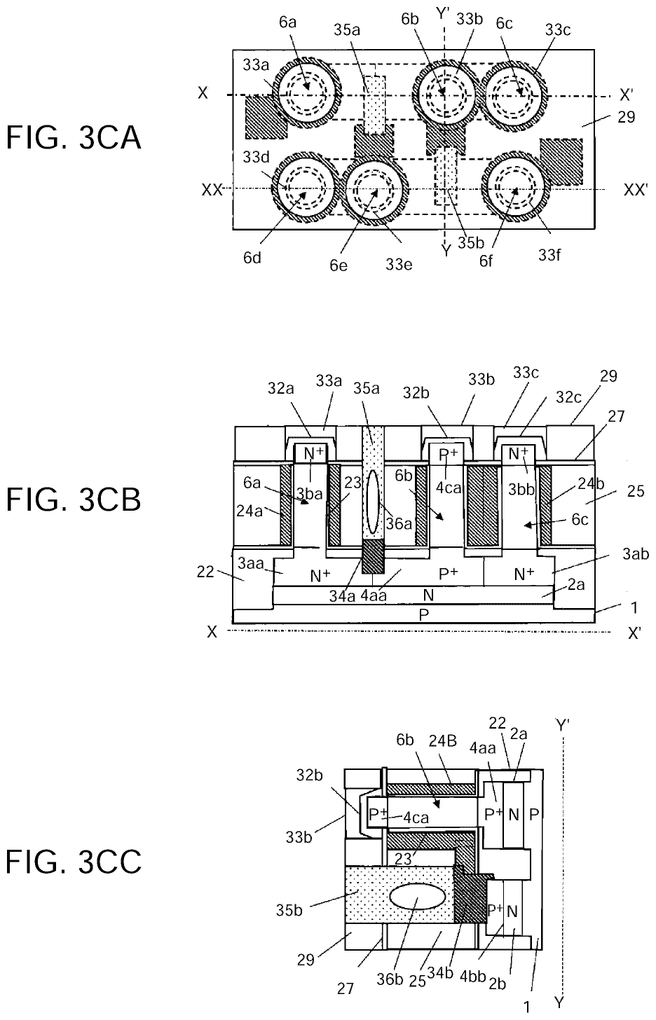

Hereinafter, a manufacturing method of an SRAM cell circuit having an SGT according to a third embodiment of the present invention will be described with reference to FIGS. 3AA to 3AC to 3CA to 3CC. In each diagram, A represents a plan view, B represents a sectional structural diagram taken along an X-X′ line in A, and C represents a sectional structural diagram taken along a Y-Y′ line in A.

Steps up to FIGS. 1IA to 1IC described in the first embodiment are performed. A HfO₂ layer (not illustrated) and a TiN layer (not illustrated) are deposited using ALD (Atomic Layered Deposition) and a SiO₂ layer (not illustrated) is deposited by a CVD method so as to cover the entire stack. The HfO₂ layer, the TiN layer, and the SiO₂ layers are polished by a CMP method so that upper surfaces thereof equal upper surface positions of the mask material layers 7a to 7f. Using the mask material layers 7a to 7f as a mask, the TiN layer and the SiO₂ layer are etched by an RIE method so that upper surface positions thereof are in vicinity of lower end positions of the N⁺ layers 3ba, 3bb, 3Ba, and 3Bb and the P⁺ layers 4ca and 4Ca to form a TiN layer 24 and a SiO₂ layer 25A as shown in FIGS. 3AA to 3AC. A SiN layer (not illustrated) is deposited on the entire stack. By etching the SiN layer by an RIE method, SiN layers 26a, 26b, 26c, and 26d are formed on side surfaces of the N⁺ layers 3ba, 3bb, 3Ba, and 3Bb, the P⁺ layers 4ca and 4Ca, and the mask material layers 7a to 7f. In this case, when a distance between the P⁺ layer 4ca and the N⁺ layer 3bb is short, the SiN layer 26b is formed connected between the P⁺ layer 4ca and the N⁺ layer 3bb. In a similar manner, when a distance between the P⁺ layer 4ca and the N⁺ layer 3Ba is short, the SiN layer 26c is formed connected between the P⁺ layer 4Ca and the N⁺ layer 3Ba. A mask material layer 26A partially overlapping with the SiN layer 26a, a mask material layer 26B partially overlapping with the SiN layer 26b, a mask material layer 26C partially overlapping with the SiN layer 26c, and a mask material layer 26D partially overlapping with the SiN layer 26d in a plan view are formed. In this case, a thickness L1 of the mask material layers 26A to 26D in a plan view is formed smaller than a thickness L2 of TiN layers.

Next, as shown in FIGS. 3BA to 3BC, using the mask material layers 7a to 7d and 26A to 26D and the SiN layers 26a to 26d as masks, the SiO₂ layer 25A and the TiN layer 24 are etched to form TiN layers 24A, 24B, 24C, and 24D. In this case, the SiO₂ layer 25A below the mask material layers 26A to 26D is retained. Due to the etching, the thickness of the TiN layers 24A to 24D which surround the Si pillars 6a to 6f is formed thin at L1 in a state where the thickness L2 of the bottom parts of the TiN layers 24A to 24D is maintained.

Next, by performing steps shown in FIGS. 1JA to 1JC to FIGS. 1RA to 1RC, the SiO₂ layers 35a and 35b including the holes 36a and 36b are formed on the W layers 34a and 34b as shown in FIGS. 3CA to 3CC. In this case, the W layers 34a to 34b are formed on bottom parts of the contact holes C1 and C2 (refer to FIGS. 1QA to 1QC). The contact holes C1 and C2 are formed on the thick TiN layers 24B and 24C with the thickness L2. Subsequently, by performing the steps shown in FIGS. 1SA to 1SC to FIGS. 1UA to 1UC, an SRAM cell is formed on the P layer substrate 1.

The manufacturing method according to the third embodiment produces the following features.

### (Feature 1)

Usually, the thickness of the gate TiN layers 24A to 24D need only be a thickness that enables a predetermined work function to be obtained and may be around 2 to 5 nm. In order to increase a scale of integration of an SRAM cell on a plane, the thinner the thickness of the gate TiN layers 24A to 24D, the better. However, when the thickness of the TiN layers 24B and 24C which come into contact with the contact holes C1 and C2 is thin, there may be cases where the contact holes C1 and C2 penetrate the TiN layers 24B and 24C during formation of the contact holes C1 and C2. In this case, the possibility of poor connection between the TiN layers 24B and 24C and the W layers 34a and 34b increases. In contrast, according to the present embodiment, the thickness of the TiN layers 24B and 24C in parts which come into contact with the contact holes C1 and C2 can be increased by reducing the thickness of the TiN layers 24A to 24D in the outer circumferential parts of the Si pillars 6a and 6f. Accordingly, poor connection between the TiN layers 24B and 24C and the W layers 34a and 34b can be prevented.

### (Feature 2)

In a normal semiconductor chip including an SRAM, a logic circuit is formed around an SRAM cell region. In the logic circuit, a plurality of SGTs are connected by conducting electrodes. As the conducting electrode, a TiN layer which is a same layer as the thick TiN layers 24B and 24C in a portion to be connected to the W layers 34a and 34b is used. The TiN layer is required to have low resistance. From this perspective, the thickness of the TiN layer must be increased. On the other hand, in the SGTs in the logic circuit region, the gate TiN layers in a portion surrounding the Si pillars are desirably thinner in order to increase the scale of integration. In contrast, in the present embodiment, contributions are made toward higher integration and higher performance of SGTs in the logic circuit region.

### Other Embodiments

While one SGT has been formed on one semiconductor pillar in the embodiments according to the present invention, the present invention can also be applied to circuit formation in which two or more SGTs are formed. The present invention can be applied to a connection between impurity layers in top parts of SGTs in uppermost parts of two semiconductor pillars on which two or more SGTs have been formed.

While the Si pillars 6a to 6f are formed in the first embodiment, the Si pillars may be replaced with semiconductor pillars made of other semiconductor materials. This similarly applies to other embodiments according to the present invention.

In addition, an example of an SRAM cell made up of six SGTs has been described in the first embodiment. In contrast, even when there are eight SGTs, the present invention can be applied by providing a region where the contact hole C1 is to be formed between the Si pillars 6a and 6b and providing a region where the contact hole C2 is to be formed between the Si pillars 6e and 6f. This similarly applies to other embodiments according to the present invention.

In addition, the N⁺ layers 32a, 32c, 32d, and 32f and the P⁺ layers 32b and 32e according to the first embodiment may be formed of Si or another semiconductor material layer containing donor or acceptor impurities. In addition, the N⁺ layers 32a, 32c, 32d, and 32f and the P⁺ layers 32b and 32e may be formed of different semiconductor material layers. This similarly applies to other embodiments according to the present invention.

In addition, as the SiN layer 27 in outer circumferential parts of the Si pillars 6a to 6f, the SiO₂ layers 28a to 28f formed on exposed top parts of the Si pillars 6a to 6f and side surfaces of the mask material layers 7a to 7f, and the AlO layer 29 which surrounds the SiO₂ layers 28a to 28f, another material layer made of a single layer or made up of a plurality of layers and containing an organic material or an inorganic material may be used as long as the materials serve the purpose of the present invention. This similarly applies to other embodiments according to the present invention.

In addition, in the first embodiment, the mask material layer 7 is formed of a SiO₂ layer, an AlO layer, and a SiO₂ layer. As the mask material layer 7, another material layer made of a single layer or made up of a plurality of layers and containing an organic material or an inorganic material may be used as long as the materials serve the purpose of the present invention. This similarly applies to other embodiments according to the present invention.

In addition, in the first embodiment, the band-shaped SiN layers 13aa, 13ab, 13ba, and 13bb entirely formed by an ALD method are formed on both sides of the band-shaped SiGe layers 8a and 8b as shown in FIGS. 1CA to 1CC and FIGS. 1DA to 1DC. As the band-shaped SiN layers 13aa, 13ab, 13ba, and 13bb and the band-shaped SiGe layers 8a and 8b, another material layer made of a single layer or made up of a plurality of layers and containing an organic material or an inorganic material may be used as long as the materials serve the purpose of the present invention. This similarly applies to other embodiments according to the present invention.

In addition, in the first embodiment, as shown in FIGS. 1TA to 1TC, the N⁺ layers 3aa, 3ab, 3ba, and 3bb and the P⁺ layers 4aa and 4bb to be a source or a drain of an SGT are formed connected on the N layers 2a and 2b in lower parts of the Si pillars 6a to 6f. In contrast, the N⁺ layers 3aa, 3ab, 3ba, and 3bb and the P⁺ layers 4aa and 4bb may be formed in bottom parts of the Si pillars 6a to 6f and the N⁺ layers 3aa, 3ab, 3ba, and 3bb and the P⁺ layers 4aa and 4bb may be connected to each other via a metal layer or an alloy layer. In addition, the N⁺ layers 3aa, 3ab, 3ba, and 3bb and the P⁺ layers 4aa and 4bb may be formed connected to side surfaces of the bottom parts of the Si pillars 6a to 6f. As described above, the N⁺ layers 3aa, 3ab, 3ba, and 3bb and the P⁺ layers 4aa and 4bb to be a source or a drain of an SGT may be formed inside the bottom parts of the Si pillars 6a to 6f, or in contact with an outer side of side surfaces of the Si pillars 6a to 6f, and in an outer circumference of the Si pillars 6a to 6f, and the respective layers may be electrically connected by other conductive materials. This similarly applies to other embodiments according to the present invention.

In addition, a material of the various wiring metal layers 34a, 34b, WL, Vdd, Vss, BL, and RBL is not limited to a metal and may be a conductive material layer such as a semiconductor layer containing a large amount of an alloy, acceptor impurities, or donor impurities and may be constructed by a single layer or a plurality of layers of the conductive material layer. This similarly applies to other embodiments according to the present invention.

Since the thin single crystal Si layers 45a to 45e are layers for forming the P⁺ layer 46b and the N⁺ layers 46a, 46c, 46d, and 46f with good crystallinity, other single crystal semiconductor thin film layers may be used as long as a same purpose can be served.

In the first embodiment, the Si pillars 6a to 6f have a circular shape in a plan view. The shape of a part of or all of the Si pillars 6a to 6f in a plan view may be a circle, an ellipse, a shape elongated in one direction, or the like. In addition, even in a logic circuit region which is formed separated from the SRAM cell region, a mixture of Si pillars with different shapes in a plan view can be formed in the logic circuit region in accordance with logic circuit design. These descriptions similarly apply to other embodiments according to the present invention.

In addition, in the first embodiment, the N⁺ layers 3aa, 3ab, 3aB, and 3bB and the P⁺ layers 4aa and 4bb are formed so as to be connected to bottom parts of the Si pillars 6a to 6f. An alloy layer made of a metal, silicide, or the like may be formed on upper surfaces of the N⁺ layers 3aa, 3ab, 3aB, and 3bB and the P⁺ layers 4aa and 4bb. In addition, a source or drain impurity region of an SGT may be formed by forming a P⁺ layer or an N⁺ layer containing donor or acceptor impurity atoms by, for example, an epitaxial crystal growth method on outer circumferences of the bottom parts of the Si pillars 6a to 6f. In this case, an N⁺ layer or a P⁺ layer may or may not be formed inside Si pillars in contact with the N⁺ layer or the P⁺ layer formed by the epitaxial crystal growth method. Alternatively, an extended metal layer or an extended alloy layer may be provided in contact with the P⁺ layer or the N⁺ layer. This similarly applies to other embodiments according to the present invention.

In addition, while SGTs are formed on the P layer substrate 1 in the first embodiment, a SOI (Silicon On Insulator) substrate may be used instead of the P layer substrate 1. Alternatively, a substrate made of other materials may be used as long as the role of a substrate is served. This similarly applies to other embodiments according to the present invention.

In addition, while SGTs that constitute a source and a drain using N⁺ layers and P⁺ layers which have conductivity of the same polarity in upper and lower positions of the Si pillars 6a to 6f have been described in the first embodiment, the present invention can also be applied to tunnel SGTs having a source and a drain with different polarities. This similarly applies to other embodiments according to the present invention.

In addition, in the second embodiment, the thin single-crystal Si layers 45a to 45e are formed by an ALD method and N⁺ or P⁺ layers 46a to 46e are formed by an epitaxial crystal growth method. The thin single-crystal Si layers 45a to 45e are material layers for obtaining the N⁺ or P⁺ layers 46a to 46e with good crystallinity. A single layer or a plurality of layers of other material layers may be used as long as the material layers enable the N⁺ or P⁺ layers 46a to 46e with good crystallinity to be obtained.

In addition, in the state shown in FIGS. 1JA to 1JC, the mask material layers 7a, 7b, 7c, 7d, 7e, and 7f may be absent. In this case, in FIGS. 1KA to 1KC or FIGS. 1LA to 1LC, due to a step of etching the top parts of the Si pillars 6a to 6f, a step of oxidizing the top parts of the Si pillars 6a to 6f and then removing the oxide film, or the like, the upper surface positions of the top parts of the Si pillars 6a to 6f can be made lower than the AlO layer 29.

The present invention enables various embodiments and modifications to be devised without departing from the broad spirit and scope of the present invention. In addition, the embodiments described above are for explaining examples of the present invention and are not intended to limit the scope of the present invention. The embodiments and the modifications described above can be arbitrarily combined. Furthermore, even if parts of constituent features of the embodiments described above are removed as necessary, such removal of constituent features is within the technical ideas of the present invention.

A pillar-shaped semiconductor memory device and a manufacturing method thereof according to the present invention enable a high-density pillar-shaped semiconductor memory device to be obtained.

What is claimed is:

1. A manufacturing method of a pillar-shaped semiconductor memory device, comprising the steps of:
forming, on a substrate, first semiconductor pillars which are aligned on a first line in a plan view and which form first SGTs (Surrounding Gate Transistors) erected in a vertical direction, second semiconductor pillars which are adjacent to the first semiconductor pillars and which form second SGTs, third semiconductor pillars which are aligned on a second line being parallel to the first line in a plan view and which form third SGTs erected in the vertical direction, and fourth semiconductor pillars which are adjacent to the third semiconductor pillars and which form fourth SGTs;
forming a first gate insulating layer which surrounds the first semiconductor pillars, a second gate insulating layer which surrounds the second semiconductor pillars, a third gate insulating layer which surrounds the third semiconductor pillars, and a fourth gate insulating layer which surrounds the fourth semiconductor pillars;
forming a first gate conductor layer which surrounds the first gate insulating layer, a second gate conductor layer which surrounds the second gate insulating layer and which protrudes in a direction of the second line in a plan view, a third gate conductor layer which surrounds the third gate insulating layer in a plan view and which protrudes in a direction of the first line in a plan view, and a fourth gate conductor layer which surrounds the fourth gate insulating layer;
forming a first contact hole on a first connection region which connects a first impurity region in a bottom part of the first semiconductor pillars and a second impurity region in a bottom part of the second semiconductor pillars to each other and on the third gate conductor layer which protrudes in a direction of the first line in a plan view and, at the same time, forming a second contact hole on a second connection region which connects a third impurity region in a bottom part of the third semiconductor pillars and a fourth impurity region in a bottom part of the fourth semiconductor pillars to each other and on the second gate conductor layer which protrudes in a direction of the second line in a plan view;
forming a first conductor layer in a bottom part of the first contact hole and, at the same time, forming a second conductor layer in a bottom part of the second contact hole; and
forming a first hole or a first insulation material layer made of a low-permittivity material layer in the first contact hole on the first conductor layer and, at the same time, forming a second hole or a second insulation material layer made of a low-permittivity material layer in the second contact hole on the second conductor layer, wherein
the first SGTs and the fourth SGTs are select transistors of an SRAM memory cell and the second SGTs and the third SGTs are load transistors of an SRAM memory cell.

2. The manufacturing method of a pillar-shaped semiconductor memory device according to claim 1, wherein upper end positions of the first hole and the second hole are formed lower than upper end positions of the first gate conductor layer, the second gate conductor layer, the third gate conductor layer, and the fourth gate conductor layer in the vertical direction.

3. The manufacturing method of a pillar-shaped semiconductor memory device according to claim 1, wherein in the step of forming the second gate conductor layer, a thickness of the second gate conductor layer in a region in contact with the second contact hole is formed thicker than a thickness of the second gate conductor layer which surrounds the second gate insulating layer.

4. The manufacturing method of a pillar-shaped semiconductor memory device according to claim 3, further comprising the steps of:
forming a second conductor layer which surrounds the first gate insulating layer, the second gate insulating layer, the third gate insulating layer, and the fourth gate insulating layer, an upper surface position of the second conductor layer being lower than top parts of the first semiconductor pillars, the second semiconductor pillars, the third semiconductor pillars, and the fourth semiconductor pillars in the vertical direction;
forming a first mask material layer which surrounds top parts of the first semiconductor pillars, the second semiconductor pillars, the third semiconductor pillars, and the fourth semiconductor pillars;
forming: a second mask material layer which is connected to the second semiconductor pillars in a plan view, a part of the second mask material layer protruding in a direction of the second line; and a third mask material layer which is connected to the third semiconductor pillars in a plan view, a part of the third mask material layer protruding in a direction of the first line; and
forming the first gate conductor layer, the second gate conductor layer, the third gate conductor layer, and the fourth gate conductor layer by using the first mask material layer, the second mask material layer, and the third mask material layer as masks to etch the second conductor layer, wherein
a film thickness of the second gate conductor layer which overlaps with the second mask material layer in a plan view is formed thicker than a film thickness of the first mask material layer and a film thickness of the third gate conductor layer which overlaps with the third mask material layer in a plan view is formed thicker than a film thickness of the third mask material layer.

5. A pillar-shaped semiconductor memory device, comprising:
on a substrate, first semiconductor pillars which are aligned on a first line in a plan view and which form first SGTs (Surrounding Gate Transistors) erected in a vertical direction, second semiconductor pillars which are adjacent to the first semiconductor pillars and which form second SGTs, third semiconductor pillars which are aligned on a second line being parallel to the first line in a plan view and which form third SGTs erected in the vertical direction, and fourth semiconductor pillars which are adjacent to the third semiconductor pillars and which form fourth SGTs;
a first gate insulating layer which surrounds the first semiconductor pillars, a second gate insulating layer which surrounds the second semiconductor pillars, a third gate insulating layer which surrounds the third semiconductor pillars, and a fourth gate insulating layer which surrounds the fourth semiconductor pillars;
a first gate conductor layer which surrounds the first gate insulating layer, a second gate conductor layer which surrounds the second gate insulating layer and which protrudes in a direction of the second line in a plan view, a third gate conductor layer which surrounds the third gate insulating layer in a plan view and which protrudes in a direction of the first line in a plan view, and a fourth gate conductor layer which surrounds the fourth gate insulating layer;
a first contact part which extends in a vertical direction above a first connection region which connects a first impurity region in a bottom part of the first semiconductor pillars and a second impurity region in a bottom part of the second semiconductor pillars to each other and on the third gate conductor layer which protrudes in a direction of the first line in a plan view and a second contact part which extends in a vertical direction above a second connection region which connects a third impurity region in a bottom part of the third semiconductor pillars and a fourth impurity region in a bottom part of the fourth semiconductor pillars to each other and on the second gate conductor layer which protrudes in a direction of the second line in a plan view;
a first conductor layer in a bottom part of the first contact part and a second conductor layer in a bottom part of the second contact part; and
a first hole or a first insulation material layer made of a low-permittivity material layer in the first contact part on the first conductor layer and a second hole or a second insulation material layer made of a low-permittivity material layer in the second contact part on the second conductor layer, wherein
the first SGTs and the fourth SGTs are select transistors of an SRAM memory cell and the second SGTs and the third SGTs are load transistors of an SRAM memory cell.

6. The pillar-shaped semiconductor memory device according to claim 5, wherein
upper end positions of the first hole and the second hole are lower than upper end positions of the first gate conductor layer, the second gate conductor layer, the third gate conductor layer, and the fourth gate conductor layer in the vertical direction.

7. The pillar-shaped semiconductor memory device according to claim 5, wherein
a thickness of the second gate conductor layer in a region in contact with the second contact part is thicker than a thickness of the second gate conductor layer which surrounds the second gate insulating layer.
